(19) United States
(12) Patent Application Publication
(10) Pub. No.: US 2023/0282780 A1
(43) Pub. Date: Sep. 7, 2023

(54) DISPLAY DEVICE

(71) Applicant: Samsung Display Co., LTD., Yongin-si (KR)

(72) Inventors: Won Jun LEE, Seoul (KR); Dong Woo KIM, Seoul (KR); Do Yeong PARK, Hwaseong-si (KR)

(21) Appl. No.: 18/056,614

(22) Filed: Nov. 17, 2022

(30) Foreign Application Priority Data
Mar. 3, 2022 (KR) 10-2022-0027251

(51) Int. Cl. H01L 33/38; H01L 25/075; H01L 33/62

(52) U.S. Cl. CPC H01L 33/387; H01L 25/0753; H01L 33/62

(57) ABSTRACT

A display device is provided. The display device includes a first electrode extended in a first direction, a second electrode spaced apart from the first electrode in a second direction crossing the first direction, and extended in the first direction, a bank layer extended in the second direction, and surrounding subpixels, and a light emitting element on the first electrode and the second electrode, wherein at least one of the first electrode or the second electrode includes an electrode extension portion extended in the first direction, and an electrode body portion connected to the electrode extension portion, and having a width that is greater than that of the electrode extension portion, and wherein the bank layer overlaps the electrode body portion with a first width, and includes an organic insulating material.

### CROSS-REFERENCE TO RELATED APPLICATION

This application claims priority to, and the benefit of, Korean Patent Application No. 10-2022-0027251 filed on Mar. 3, 2022, in the Korean Intellectual Property Office, the contents of which in its entirety are herein incorporated by reference.

### BACKGROUND

### 1. Field

The disclosure relates to a display device.

### 2. Description of the Related Art

With the advancement of the information age, the demand for a display device for displaying an image has increased with various forms. The display device may be a flat panel display device, such as a liquid crystal display device, a field emission display device and a light emitting display panel. The light emitting display device may include an organic light emitting display device including an organic light emitting diode element as a light emitting element, an inorganic light emitting display device including an inorganic semiconductor element as a light emitting element, or a micro light emitting diode device including a micro light emitting diode as a light emitting element.

### SUMMARY

The present disclosure provides a display device that may reduce or prevent the likelihood of light emitting elements being agglomerated in an area excluding an alignment area.

The present disclosure is not limited to those mentioned above, and additional aspects of the disclosure, which are not mentioned herein, will be clearly understood by those skilled in the art from the following description of the disclosure.

According to one or more embodiments of the disclosure, a display device includes a first electrode extended in a first direction, a second electrode spaced apart from the first electrode in a second direction crossing the first direction, and extended in the first direction, a bank layer extended in the second direction, and surrounding subpixels, and a light emitting element on the first electrode and the second electrode, wherein at least one of the first electrode or the second electrode includes an electrode extension portion extended in the first direction, and an electrode body portion connected to the electrode extension portion, and having a width that is greater than that of the electrode extension portion, and wherein the bank layer overlaps the electrode body portion with a first width, and includes an organic insulating material.

The first width may be about 7 um or more.

The bank layer may have a maximum thickness of about 2 um or more.

The bank layer may have a dielectric constant of about 2 to about 4.

The bank layer may be spaced apart from another bank layer in the first direction.

The first electrode may include a first electrode extension portion extended in the first direction, and a first electrode body portion connected to the first electrode extension portion, wherein the second electrode includes a second electrode extension portion extended in the first direction, and a second electrode body portion connected to the second electrode extension portion, and wherein the first electrode extension portion has a shape that is bent in a diagonal direction inclined toward the second electrode body portion from the first direction.

The second electrode extension portion may have a shape that is bent in a diagonal direction inclined toward the first electrode body portion from the first direction.

The second electrode may include a first electrode line and a second electrode line spaced apart from each other with the first electrode interposed therebetween, wherein the display device further includes a first light emitting element between the first electrode and the first electrode line, and a second light emitting element between the first electrode and the second electrode line.

The display device may further include a first connection electrode on the first electrode, and in contact with the first light emitting element, and a second connection electrode on the second electrode, and in contact with the second light emitting element, wherein the first connection electrode and the second connection electrode are on the electrode body portion.

The second electrode may include the electrode body portion over adjacent ones of the subpixels.

A width of the electrode body portion in the second direction may be greater than a width of the bank layer in the second direction.

The electrode body portion may overlap the bank layer between the adjacent ones of the subpixels.

The display device may further include a first bank pattern extended in the second direction, and overlapped with the first electrode, and a second bank pattern spaced apart from the first electrode in the first direction, extended in the second direction, and overlapped with the second electrode, wherein the electrode body portion overlaps any one of the first bank pattern and the second bank pattern, and wherein the electrode extension portion is spaced apart from the first bank pattern and the second bank pattern in plan view.

The bank layer may overlap the first bank pattern and the second bank pattern.

According to one or more embodiments of the disclosure, a display device includes a first electrode extended in a first direction, a second electrode spaced apart from the first electrode in a second direction crossing the first direction, and extended in the first direction, a bank layer extended in the second direction, and surrounding subpixels, and a light emitting element on the first electrode and the second electrode, wherein the first electrode includes a first electrode extension portion extended in the first direction, and a first electrode body portion connected to the first electrode extension portion, and having a width that is greater than that of the first electrode extension portion, wherein the second electrode includes a second electrode extension portion extended in the first direction, and a second electrode body portion connected to the second electrode extension portion, and having a width that is greater than that of the second electrode extension portion, and wherein the first electrode extension portion has a shape that is bent in a diagonal direction inclined toward the second electrode body portion from the first direction.

The bank layer may overlap the first electrode body portion and the second electrode body portion.

The bank layer may overlap the first electrode body portion and the second electrode body portion as much as about 7 um or more.

A width of the first electrode extension portion in the second direction may be the same as that of the second electrode extension portion in the second direction.

A width of the first electrode body portion in the second direction may be less than that of the second electrode body portion in the second direction.

The first electrode extension portion may be connected to a conductive layer through a first electrode contact hole, wherein the second electrode extension portion is connected to the conductive layer through a second electrode contact hole, and wherein the first electrode contact hole and the second electrode contact hole are separated from the bank layer in plan view.

In the display device according to the embodiments of the disclosure, a bank layer may be located on electrodes that receive different voltages in an area, other than an alignment area, in a light emission area in which light emitting elements are aligned. Therefore, the display device may reduce or prevent the likelihood of an electric field, which otherwise interferes with an electric field in the alignment area of the light emitting element, being formed between the electrodes to which different voltages are applied.

The aspects of embodiments of the disclosure are not limited to those mentioned above, and more various aspects are included in the following description of the disclosure.

### BRIEF DESCRIPTION OF THE DRAWINGS

The above and other aspects of the disclosure will become more apparent by describing in detail embodiments thereof with reference to the attached drawings, in which:

FIG. 1 is a schematic plan view illustrating a display device according to one or more embodiments of the disclosure;

FIG. 2 is a circuit view illustrating a pixel of a display device according to one or more embodiments of the disclosure;

FIG. 3 is a plan view illustrating arrangement of electrodes, bank patterns, and a bank layer, which are located in one pixel of a display device according to one or more embodiments of the disclosure;

FIG. 4 is a plan view illustrating arrangement of connection electrodes and light emitting elements, which are located in one pixel in addition to FIG. 3;

FIG. 5 is a cross-sectional view taken along the line E1-E1′ of FIG. 4;

FIG. 6 is a cross-sectional view taken along the line E2-E2′ and taken along the line E3-E3′ of FIG. 4;

FIG. 7 is a schematic plan view illustrating a light emitting element according to one or more embodiments of the disclosure;

FIG. 8 is an enlarged plan view illustrating area A of FIG. 3;

FIG. 9 is a cross-sectional view taken along the line E4-E4′ of FIG. 8;

FIG. 10 is an enlarged plan view illustrating area B of FIG. 3;

FIG. 11 is a cross-sectional view taken along the line E5-E5′ of FIG. 10;

FIG. 12 is a cross-sectional view taken along the line X1-X1′ of FIG. 8;

FIG. 13 is a graph illustrating intensity of an electric field in a first direction according to a length of a first width of FIGS. 8 and 12;

FIG. 14 is a graph illustrating intensity of an electric field in a first direction according to a first thickness of a bank layer of FIGS. 8 and 12;

FIG. 15 is a plan view illustrating a display device according to one or more other embodiments of the disclosure;

FIG. 16 is a plan view illustrating arrangement of connection electrodes, a bank layer and light emitting elements, which are located in one pixel of FIG. 15; and

FIG. 17 is a cross-sectional view taken along the line E6-E6′ of FIGS. 15 and 16.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

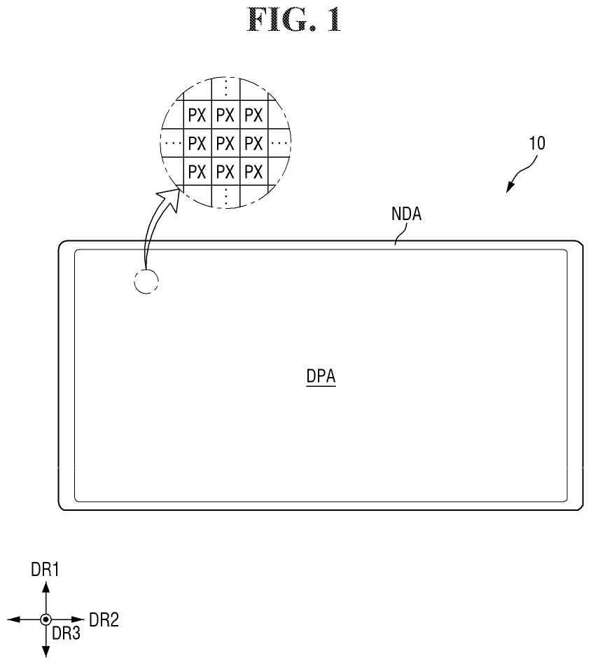

FIG. 1 is a schematic plan view illustrating a display device according to one or more embodiments of the disclosure.

Referring to FIG. 1, a display device 10 displays a moving image or a still image. The display device 10 may refer to all electronic devices that provide a display screen. For example, a television, a laptop computer, a monitor, an advertising board, Internet of Things, a mobile phone, a smart phone, a tablet personal computer (PC), an electronic watch, a smart watch, a watch phone, a head mounted display, a mobile communication terminal, an electronic diary, an electronic book, a portable multimedia player (PMP), a navigator, a game machine, a digital camera, a camcorder and the like, which provide a display screen, may be included in the display device 10.

The display device 10 includes a display panel for providing a display screen. Examples of the display panel include an inorganic light emitting diode display panel, an organic light emitting display panel, a quantum dot light emitting display panel, a plasma display panel and a field emission display panel. Hereinafter, an inorganic light emitting diode display panel is applied as an example of a display panel, but the example of the display panel is not limited thereto. Another display panel may be used when the same technical spirits are applicable thereto.

Various modifications may be made in a shape of the display device 10. For example, the display device 10 may have a rectangular shape that is long in a horizontal direction, a rectangular shape that is long in a vertical direction, a square shape, a square shape with rounded corners (vertexes), other polygonal shapes, a circular shape, etc. A shape of a display area DPA of the display device 10 may be also similar to the overall shape of the display device 10. In FIG. 1, a rectangular display device 10 that is longer in a second direction DR2 is illustrated in FIG. 1.

The display device 10 may include a display area DPA and a non-display area NDA. The display area DPA is an area in which a screen may display an image, and the non-display area NDA is an area in which a screen is not displayed. The display area DPA may be referred to as an active area, and the non-display area NDA may be referred to as a non-active area. The display area DPA may generally occupy the center of the display device 10.

The display area DPA may include a plurality of pixels PX. The plurality of pixels PX may be located in a matrix direction. A shape of each pixel PX may be a rectangular or square shape on a plane, but is not limited thereto. The shape of each pixel PX may be a rhombus shape in which each side is inclined with respect to one direction. The respective pixels PX may be located in a stripe type or an island type. Also, each of the pixels PX may include one or more light emitting elements for emitting light of a corresponding wavelength band to display a corresponding color.

The non-display area NDA may be located near the display area DPA. The non-display area NDA may fully or partially surround the display area DPA. The display area DPA may be rectangular in shape, and the non-display area NDA may be adjacent to four sides of the display area DPA. The non-display area NDA may constitute a bezel of the display device 10. Lines or circuit drivers included in the display device 10 may be located in the non-display areas NDA, or external devices may be packaged therein.

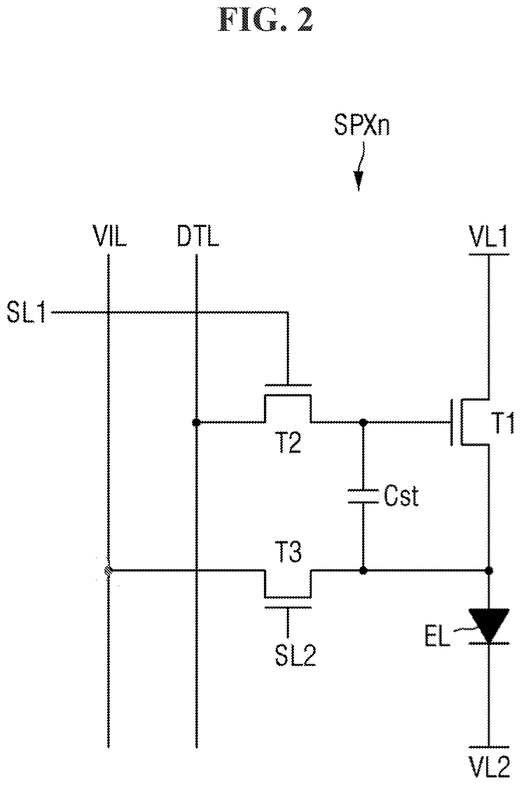

FIG. 2 is a circuit view illustrating a pixel of a display device according to one or more embodiments of the disclosure.

Referring to FIG. 2, each subpixel SPXn of the display device 10 according to one or more embodiments includes three transistors T1, T2, and T3 and one storage capacitor Cst, in addition to a light emitting diode EL.

The light emitting diode EL emits light in accordance with a current supplied through the first transistor T1. The light emitting diode EL includes a first electrode, a second electrode, and at least one light emitting element located between the first electrode and the second electrode. The light emitting element may emit light of a corresponding wavelength band by an electrical signal transferred from the first electrode and the second electrode.

One end of the light emitting diode EL may be connected to a source electrode of the first transistor T1, and the other end thereof may be connected to a second voltage line VL2 to which a low potential voltage (hereinafter, referred to as “second power voltage”), which is lower than a high potential voltage (hereinafter, referred to as “first power voltage”) of a first voltage line VL1, is supplied.

The first transistor T1 determines the current flowing from the first voltage line VL1, to which the first power voltage is supplied, to the light emitting diode EL in accordance with a voltage difference between a gate electrode and a source electrode. For example, the first transistor T1 may be a driving transistor for driving the light emitting diode EL. The gate electrode of the first transistor T1 may be connected to a source electrode of the second transistor T2, the source electrode thereof may be connected to a first electrode of the light emitting diode EL, and a drain electrode thereof may be connected to the first voltage line VL1 to which the first power voltage is applied.

The second transistor T2 is turned on by a scan signal of a first scan line SL1 to connect a data line DTL to the gate electrode of the first transistor T1. A gate electrode of the second transistor T2 may be connected to the first scan line SL1, the source electrode thereof may be connected to the gate electrode of the first transistor T1, and a drain electrode thereof may be connected to the data line DTL.

The third transistor T3 is turned on by a scan signal of a second scan line SL2 to connect an initialization voltage line VIL to one end of the light emitting diode EL. A gate electrode of the third transistor T3 may be connected to the second scan line SL2, a drain electrode thereof may be connected to the initialization voltage line VIL, and a source electrode thereof may be connected to one end of the light emitting diode EL or to the source electrode of the first transistor T1.

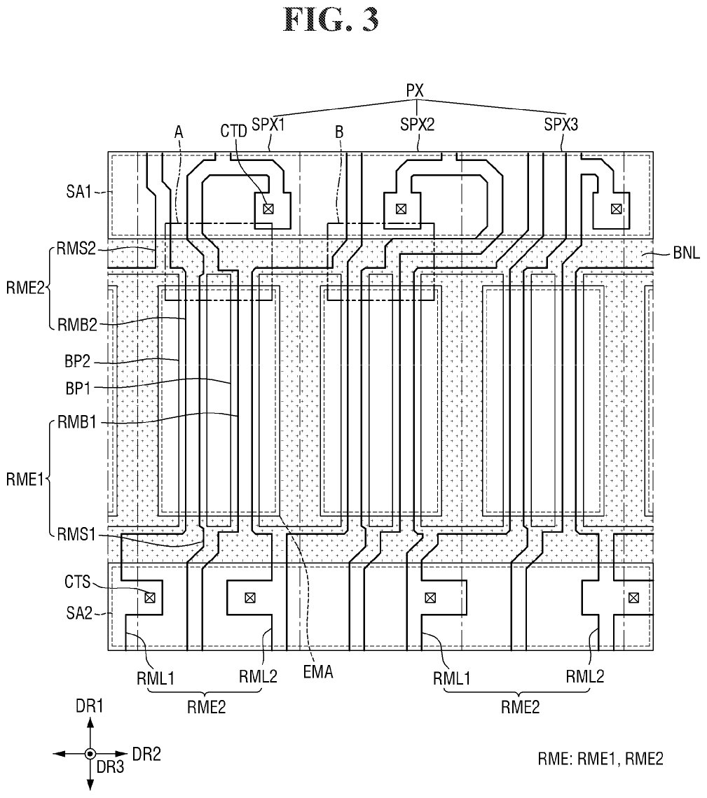

In one or more embodiments, the source electrode and the drain electrode of each of the transistors T1, T2, and T3 are not limited to those described above. Each of the transistors T1, T2, and T3 may be formed of a thin film transistor. In FIG. 3, each of the transistors T1, T2, and T3 is formed of an N-type metal oxide semiconductor field effect transistor (MOSFET), but is not limited thereto. That is, each of the transistors T1, T2, and T3 may be formed of a P-type MOSFET, or one or more of the transistors T1, T2, and T3 may be an N-type MOSFET, while the others may be formed of a P-type MOSFET.

The storage capacitor Cst is formed between the gate electrode and the source electrode of the first transistor T1. The storage capacitor Cst stores a differential voltage between a gate voltage and a source voltage of the first transistor T1.

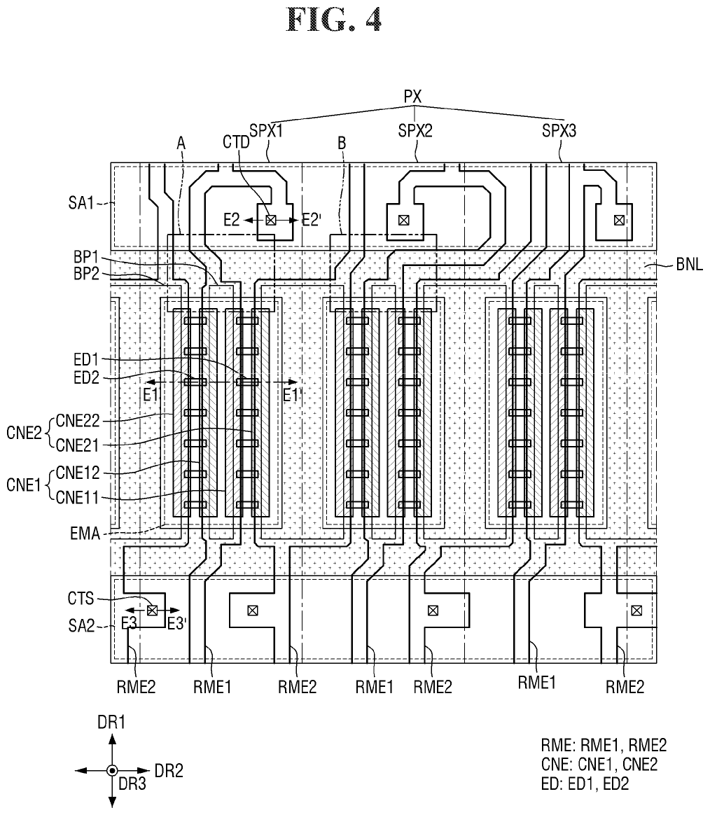

FIG. 3 is a plan view illustrating arrangement of electrodes, bank patterns, and a bank layer, which are located in one pixel of a display device according to one or more embodiments of the disclosure. FIG. 4 is a plan view illustrating arrangement of connection electrodes and light emitting elements, which are located in one pixel in addition to FIG. 3.

FIG. 3 and FIG. 4 illustrate a planar arrangement of electrodes RME: RME1 and RME2, bank patterns BP1 and BP2, a bank layer BNL, a plurality of light emitting elements ED, and connection electrodes CNE: CNE1 and CNE2, which are located in one pixel PX of the display device 10.

Each of the pixels PX of the display device 10 may include a plurality of subpixels SPXn. For example, one pixel PX may include a first subpixel SPX1, a second subpixel SPX2, and a third subpixel SPX3. The first subpixel SPX1 may emit light of a first color, the second subpixel SPX2 may emit light of a second color, and the third subpixel SPX3 may emit light of a third color. For example, the first color may be blue, the second color may be green, and the third color may be red, but the disclosure is not limited thereto. The respective subpixels SPXn may emit light of the same color. In one or more embodiments, the respective subpixels SPXn may blue emit. Although one pixel PX is illustrated as including three subpixels SPXn, it is not limited thereto, and the pixel PX may include a larger number of subpixels SPXn.

Each subpixel SPXn of the display device 10 may include a light emission area EMA and a non-light emission area. The light emission area EMA may be an area in which a light emitting element ED is located to emit light of a corresponding wavelength band. The non-light emission area may be an area in which the light emitting element ED is not located, and light emitted from the light emitting element ED does not reach there, so that the light is not emitted therefrom.

The light emission area EMA may include an area in which the light emitting element ED is located, and an area in which the light emitted from the light emitting element ED is emitted to an area adjacent to the light emitting element ED. For example, the light emission area EMA may also include an area where the light emitted from the light emitting element ED is reflected or refracted by another member. The plurality of light emitting elements ED may be located in the respective subpixels SPXn, and may include an area in which the subpixels are located and an area adjacent to the above area to form the light emission area.

Each subpixel SPXn may further include sub-areas SA1 and SA2 located in the non-light emission area. The sub-areas SA1 and SA2 may include a first sub-area SA1 located on an upper side, which is one side of the light emission area EMA in the first direction DR1, and a second sub-area SA2 located on a lower side, which is the other side of the light emission area EMA in the first direction DR1. The light emission area EMA and the sub-areas SA1 and SA2 may be alternately arranged in the first direction DR1 in accordance with the arrangement of the pixels PX and the subpixel SPXn. For example, the plurality of light emission areas EMA may be repeatedly arranged in the first direction DR1 with the first sub-area SA1 or the second sub-area SA2, which is interposed therebetween. The light emission areas EMA may be repeatedly located in the second direction DR2, and the first and second sub-areas SA1 and SA2 may extend in the second direction DR2 in the display area DPA, but the disclosure is not limited thereto, and the light emission areas EMA and the sub-areas SA1 and SA2 in the plurality of pixels PX may have an arrangement that is different from that of FIGS. 2 and 3.

The first sub-area SA1 and the second sub-area SA2 may be areas in which subpixel SPXn adjacent to each other in the first direction DR1 are shared. For example, the second sub-area SA2 may be an area shared by an (i)th subpixel (e.g., subpixel SPXn shown in FIGS. 3 and 4) and an (i+1)th subpixel, which are adjacent to each other in the first direction DR1. The first sub-area SA1 may be located on an upper side of the light emission area EMA of the (i)th subpixel, and the second sub-area SA2 may be located on an upper side of the light emission area of the (i+1)th subpixel.

In the sub-areas SA1 and SA2, the light emitting elements ED are not located so that light is not emitted, but a portion of the electrodes RME located in the respective subpixels SPXn may be located. The electrodes RME located in different subpixels SPXn may extend in the first direction DR1.

The display device 10 according to one or more embodiments of the disclosure may include a plurality of electrodes RME: RME1 and RME2, bank patterns BP1 and BP2, a bank layer BNL, light emitting elements ED, and connection electrodes CNE: CNE1 and CNE2.

The plurality of bank patterns BP1 and BP2 may be located in the light emission area EMA of each subpixel SPXn. The bank patterns BP1 and BP2 may have a shape extended in the first direction DR1 with a width (e.g., predetermined width) in the second direction DR2.

For example, the bank patterns BP1 and BP2 may include a first bank pattern BP1 and a second bank pattern BP2, which are spaced apart from each other in the second direction DR2 in the light emission area EMA of each subpixel SPXn. The first bank pattern BP1 is located at the center of the light emission area EMA, and the second bank patterns BP2 are spaced apart from each other with the first bank pattern BP1 interposed therebetween. The first bank pattern BP1 and the second bank pattern BP2 may be alternately located along the second direction DR2, and may be located in an island pattern in the display area DPA. A plurality of light emitting elements ED may be located between the first bank pattern BP1 and the second bank pattern BP2.

Widths of the first bank pattern BP1 and the second bank pattern BP2 in the second direction DR2 may be different from each other. The width of the first bank pattern BP1 in the second direction DR2 may be less than that of the second bank pattern BP2 in the second direction DR2. The first bank pattern BP1 is located in the light emission area EMA of each subpixel SPXn, whereas the second bank pattern BP2 may be located over the light emission area EMA of two subpixels SPXn adjacent to each other in the second direction DR2. The second bank pattern BP2 may be located over a boundary of the subpixels SPXn adjacent to each other in the second direction DR2, and may overlap a portion of the bank layer BNL, which extends in the first direction DR1, but the disclosure is not limited thereto, and the first and second bank patterns BP1 and BP2 may have the same width.

The first bank pattern BP1 and the second bank pattern BP2 may have the same length in the first direction DR1, and may be longer than the length of the light emission area EMA surrounded by the bank layer BNL in the first direction DR1. The first bank pattern BP1 and the second bank pattern BP2 may overlap a portion of the bank layer BNL, which extends in the second direction DR2, but are not limited thereto. The bank patterns BP1 and BP2 may be integrated with the bank layer BNL, or may be spaced apart from the portion of the bank layer BNL, which extends in the second direction DR2. In this case, the length of the bank patterns BP1 and BP2 in the first direction DR1 may be the same as, or less than, the length of the light emission area EMA surrounded by the bank layer BNL in the first direction DR1.

Although one first bank pattern BP1 and two second bank patterns BP2 different from each other are located for each subpixel SPXn, the present disclosure is not limited thereto. The number and shape of the bank patterns BP1 and BP2 may vary depending on the number or arrangement structure of the electrodes RME.

The plurality of electrodes RME: RME1 and RME2 are located in each subpixel SPXn in a shape extended in one direction. The plurality of electrodes RME1 and RME2 may extend in the first direction DR1, and thus may be located in the light emission area EMA of the subpixel SPXn, and may be spaced apart from each other in the second direction DR2. The plurality of electrodes RME may be electrically connected to the light emitting element ED, but are not limited thereto. The electrodes RME may not be electrically connected to the light emitting element ED.

The display device 10 may include a first electrode RME1 located in each subpixel SPXn, and a second electrode RME2 located over different subpixels SPXn. The first electrode RME1 may be adjacent to the center of the subpixel SPXn, and may be located over the light emission area EMA and the sub-areas SA1 and SA2. The second electrode RME2 may be spaced apart from the first electrode RME1 in the second direction DR2 in the light emission area EMA, and may be located over the plurality of subpixels SPXn. The first electrode RME1 and the second electrode RME2 may have a shape extended generally in the first direction DR1 (e.g., a length extended in the first direction DR1), and a shape of a portion located in the light emission area EMA may be different from each other. The first electrode RME1 may be located at the center of the subpixel SPXn, and the portion located in the light emission area EMA may be located on the first bank pattern BP1. The second electrode RME2 may be located on respective sides with respect to the second direction DR2 at the center of the subpixel SPXn, and the portion located in the light emission area EMA may be located on the second bank pattern BP2.

According to one or more embodiments, the electrodes RME1 and RME2 may include a portion extended in the first direction DR1, and a portion having a width that is widened near the light emission area EMA. The electrodes RME1 and RME2 may respectively include electrode extension portions RMS1 and RMS2 extended in the first direction DR1, and electrode body portions RMB1 and RMB2 connected from the electrode extension portions RMS1 and RMS2, and having a width in the second direction DR2 that is wider than that of the electrode extension portions RMS1 and RMS2.

The first electrode RME1 may include a first electrode extension portion RMS1 extended in the first direction DR1, and may include a first electrode body portion RMB1 that is relatively wide in the second direction DR2. The second electrode RME2 may include a second electrode extension portion RMS2 extended in the first direction DR1, and may include a second electrode body portion RMB2 that is relatively wide in the second direction DR2.

The electrode extension portions RMS1 and RMS2 may be located to overlap a portion of the bank layer BNL, which extends in the second direction DR2, and may be located in the sub-areas SA1 and SA2. The electrode extension portions RMS1 and RMS2 might not be located in the light emission area EMA. The electrode extension portions RMS1 and RMS2 may extend from the electrode body portions RMB1 and RMB2 in the first direction DR1, and may have a shape that is at least partially bent. The electrode extension portions RMS1 and RMS2 may extend from one side deviated from the center of the electrode body portions RMB1 and RMB2 in the first direction DR1. For example, the first electrode extension portion RMS1 may protrude more to a right side or to a left side than the center of the first electrode body portion RMB1, and may generally extend in the first direction DR1. The second electrode extension portion RMS2 may be more protruded to a right side or a left side than the center of the second electrode body portion RMB2, and may generally extend in the first direction DR1. The electrode extension portions RMS1 and RMS2 may have a shape that is partially bent to ensure electrode contact holes CTD and CTS in a space (e.g., predetermined space), or may extend to be inclined from one direction.

The electrode body portions RMB1 and RMB2 may be located to partially overlap the bank layer BNL, and may be located in the light emission area EMA. The electrode body portions RMB1 and RMB2 may have a shape extended in the first direction DR1 with a width (e.g., predetermined width) in the second direction DR2. The first electrode body portion RMB1 may be located at the center of the subpixel SPXn, and may be located on the first bank pattern BP1. Both ends of the first electrode body portion RMB1 may overlap the portion of the bank layer BNL, which extends in the second direction DR2. The second electrode body portion RMB2 may be located on both sides of the center of the subpixel SPXn in the second direction DR2, and may be located on the second bank pattern BP2. The second electrode body portion RMB2 may overlap both the portion of the bank layer BNL that extends in the first direction DR1, and the portion of the bank layer BNL that extends in the second direction DR2. Both ends of the second electrode body portion RMB2 may overlap the portion of the bank layer BNL, which extends in the second direction DR2. Because the second electrode body portion RMB2 is located over the subpixels SPXn adjacent to each other in the second direction DR2, the second electrode body portion RMB2 may overlap the portion of the bank layer BNL located between the light emission areas EMA of the subpixels SPXn, which extends in the first direction DR1.

The second electrodes RME2 may generally extend in the first direction DR1 and may be located between the subpixels SPXn adjacent to each other in the second direction DR2. The second electrodes RME2 may be divided into different electrode lines RML1 and RML2, which are located on respective sides in the second direction DR2 based on the first electrode RME1. The plurality of second electrodes RME2 include a first electrode line RML1 and a second electrode line RML2, which are different from each other, and which may be alternately located in the second direction DR2. For example, based on the first subpixel SPX1, the second electrode RME2 located on the left side of the first electrode RME1 may be the first electrode line RML1, and the second electrode RME2 located on the right side of the first electrode RME1 may be the second electrode line RML2. In the second subpixel SPX2, the second electrode RME2 located on the left side of the first electrode RME1 may be the second electrode line RML2, and the second electrode RME2 located on the right side of the first electrode RME1 may be the first electrode line RML1. In the third subpixel SPX3, the second electrode RME2 located on the left side of the first electrode RME1 may be the first electrode line RML1, and the second electrode RME2 located on the right side of the first electrode RME1 may be the second electrode line RML2.

The width of the first electrode body portion RMB1 in the second direction DR2 may be less than that of the second electrode body portion RMB2 in the second direction DR2. The width of the first electrode extension portion RMS1 in the second direction DR2 may be the same as, or different from, that of the second electrode extension portion RMS2 in the second direction DR2. The width of the first electrode extension portion RMS1 and the second electrode extension portion RMS2 may be relatively small so that the first electrode extension portion RMS1 and the second electrode extension portion RMS2 may be located between the sub-areas SA1 and SA2, whereas the width of the first electrode body portion RMB1 and the second electrode body portion RMB2 may be relatively great. Each of the first electrode body portion RMB1 and the second electrode body portion RMB2 may have a width that is greater than that of each of the first bank pattern BP1 and the second bank pattern BP2, and may be located to cover both sides of the first bank pattern BP1 and the second bank pattern BP2 in the first direction DR1 and the second direction DR2. An interval between the first bank pattern BP1 and the second bank pattern BP2 may be greater than that between the first electrode RME1 and the second electrode RME2. According to one or more embodiments, the electrode body portions RMB1 and RMB2 may have a maximum width that is greater than the width of the bank patterns BP1 and BP2. The width of the second electrode body part RMB2 may be greater than that of the portion of the bank layer BNL, which extends in the first direction DR1.

The first electrode RME1 may be located to correspond to any one of the subpixels SPXn, whereas the second electrode RME2 may be located over the subpixels SPXn to which the second electrode body portion RMB2 is adjacent. The subpixels SPXn adjacent to each other in the second direction DR2 may share the second electrode body portion RMB2 of the second electrode RME2.

In one or more embodiments, the second electrode body portion RMB2 of the second electrode RME2 may be located to cover a portion between the light emission areas EMA of the adjacent subpixels SPXn. A plurality of light emitting elements ED may be located in each light emission area EMA, and light emitting elements ED may be located between the first bank pattern BP1 and the second bank pattern BP2. As described below, the light emitting elements ED may be located such that respective ends thereof are placed on the electrodes RME1 and RME2 by an electric field generated on the first electrode RME1 and the second electrode RME2 between the first bank pattern BP1 and the second bank pattern BP2.

The first electrode extension portion RMS1 of the first electrode RME1 may be in contact with a first conductive pattern CDP1 of a third conductive layer through a first electrode contact hole CTD in the first sub-area SA1. The first electrode contact hole CTD may not overlap the bank layer BNL. The second electrode extension portion RMS2 of the second electrode RME2 may be in contact with a second conductive pattern CDP2 of the third conductive layer through a second electrode contact hole CTS in the second sub-area SA2. In one or more embodiments, the first electrode RME1 and the second electrode RME2 may further include a contact portion connected to the connection electrode CNE in the sub-areas SA1 and SA2.

The electrode extension portions RMS1 and RMS2 may connect the electrode body portions RMB1 and RMB2 spaced apart from each other in the first direction DR1 so that the electrodes RME1 and RME2 are extended over the display area DPA in the first direction DR1. For example, the electrode extension portions RMS1 and RMS2 may extend the electrode body portions RMB1 and RMB2 of the (i)th subpixel SPXn and the electrode body portions of the (i+1)th subpixel SPXn. Therefore, the first electrode RME1 and the second electrode RME2 may extend over the first direction DR1.

One first electrode RME1 and the second electrodes RME2 that are different from each other are illustrated as being located in each of the subpixels SPXn, but are not limited thereto. For example, in the display device 10, a larger number of electrodes RME may be located in one subpixel SPXn, or the arrangement and shape of the electrodes RME may vary.

The bank layer BNL may be located to surround the plurality of subpixels SPXn, the light emission area EMA, and the sub-areas SA1 and SA2. The bank layer BNL may be located between the subpixels SPXn adjacent to each other in the first direction DR1 and the second direction DR2, and may be located between the light emission areas EMA. The bank layer BNL may be located between the first sub-area SA1 and the light emission area EMA, and may be located between the second sub-area SA2 and the light emission area EMA. The subpixels SPXn, the light emission area EMA, and the sub-areas SA1 and SA2 of the display device 10 may be partitioned by the arrangement of the bank layer BNL, and may be areas opened by the bank layer BNL. Intervals between the plurality of subpixel SPXn and the light emission areas EMA, and the sub-areas SA1 and SA2 may vary depending on the width of the bank layer BNL.

The bank layer BNL may include a portion extended in the first direction DR1 and the second direction DR2 on a plane. The bank layer BNL includes a portion extended in the second direction DR2 from a front surface of the display area DPA, but the portions of the bank layer BNL, which are extended in the first direction DR1, may be spaced apart from each other in the second direction DR2 for each subpixel SPXn. The bank layer BNL may be located over a boundary of the subpixels SPXn extended in the second direction DR2 to partition the subpixels SPXn adjacent to each other in the second direction DR2. In addition, the bank layer BNL may be located to surround the light emission areas EMA located for the respective subpixels SPXn, thereby partitioning the light emission areas EMA.

The plurality of light emitting elements ED may be located in the light emission area EMA. The light emitting elements ED may be located between the bank patterns BP1 and BP2, and may be spaced apart from each other in the first direction DR1. In one or more embodiments, the light emitting element ED may have a shape extended in one direction, and both ends thereof may be located on the different electrodes RME. The light emitting element ED may be longer than an interval between the electrodes RME spaced apart from each other in the second direction DR2. The light emitting elements ED may generally extend to be perpendicular to the first direction DR1 in which the electrodes RME are extended, but are not limited thereto, and the light emitting elements ED may extend toward the second direction DR2 or toward a direction inclined with respect to the second direction DR2.

The light emitting element ED may include a first light emitting element ED1 having both ends located on one of the first electrode RME1 and the second electrode RME2, and a second light emitting element ED2 having both ends located on the first electrode RME1 and the other second electrode RME2. Based on the first subpixel SPX1, the first light emitting element ED1 may be located on the second electrode RME2 of the second electrode line RML2, and the second light emitting element ED2 may be located on the second electrode RME2 of the first electrode line RML1. The first light emitting elements ED1 may be located on the right side of the first electrode RME1, and the second light emitting elements ED2 may be located on the left side of the first electrode RME1. The first and second light emitting elements ED1 and ED2 may be located on the first electrode RME1 and the second electrode RME2, respectively, and the second electrodes RME2 on which the first and second light emitting elements ED1 and ED2 are located may be different from each other.

As the second electrodes RME2 include the second electrode body portion RMB2 and are located in their respective subpixels SPXn that are different from each other, a portion of the light emitting elements ED located in the different subpixels SPXn are located on the same second electrode RME2. For example, one end of the first light emitting element ED1 of the first subpixel SPX1 may be located on the second electrode RME2 of the second electrode line RML2, and one end of the second light emitting element ED2 of the second subpixel SPX2 may be also located on the second electrode RME2 of the second electrode line RML2.

The connection electrodes CNE: CNE1 and CNE2 may be located on the electrodes RME and the bank patterns BP1 and BP2. The connection electrodes CNE may be spaced apart from each other with a shape extended in one direction, respectively. The connection electrodes CNE may be in contact with the light emitting element ED, and may be electrically connected to the electrode RME or the conductive layer therebelow.

The connection electrodes CNE may include a first connection electrode CNE1 and a second connection electrode CNE2 located in each subpixel SPXn.

The first connection electrode CNE1 may be located on the first electrode body portion RMB1 of the first electrode RME1 with a shape extended in the first direction DR1. The first connection electrode CNE1 may include a first sub-connection electrode CNE11 and a second sub-connection electrode CNE12, which are located to overlap the first bank pattern BP1 and the first electrode RME1. The first sub-connection electrode CNE11 may be located on the right side of the first electrode RME1, and the second sub-connection electrode CNE12 may be located on the left side of the first electrode RME1.

The second connection electrode CNE2 may be spaced apart from the first connection electrode CNE1 in the second direction DR2, and may be located on the second electrode body portion RMB2 of the second electrode RME2 with a shape extended in the first direction DR1. The second connection electrode CNE2 may include a third sub-connection electrode CNE21 and a fourth sub-connection electrode CNE22, which are located to overlap the second bank pattern BP2 and the second electrode RME2. The third sub-connection electrode CNE21 is the second electrode RME2 located on the right side of the first electrode RME1, and may be located on the second electrode line RML2 based on the first subpixel SPX1. The fourth sub-connection electrode CNE22 is the second electrode RME2 located on the left side of the first electrode RME1, and may be located on the first electrode line RML1 based on the first subpixel SPX1.

In one or more embodiments, each of the first sub-connection electrode CNE11 and the second sub-connection electrode CNE12 further includes a contact portion located in the sub-areas SA1 and SA2, and may be in contact with the first electrode RME1 through the contact portion, or may be directly in contact with the first conductive pattern CDP1 that is a lower conductive layer. In addition, each of the third sub-connection electrode CNE21 and the fourth sub-connection electrode CNE22 may further include a contact portion located in the sub-areas SA1 and SA2, and may be in contact with the second electrode RME2 through the contact portion, or may be directly in contact with the second conductive pattern CDP2 that is a lower conductive layer.

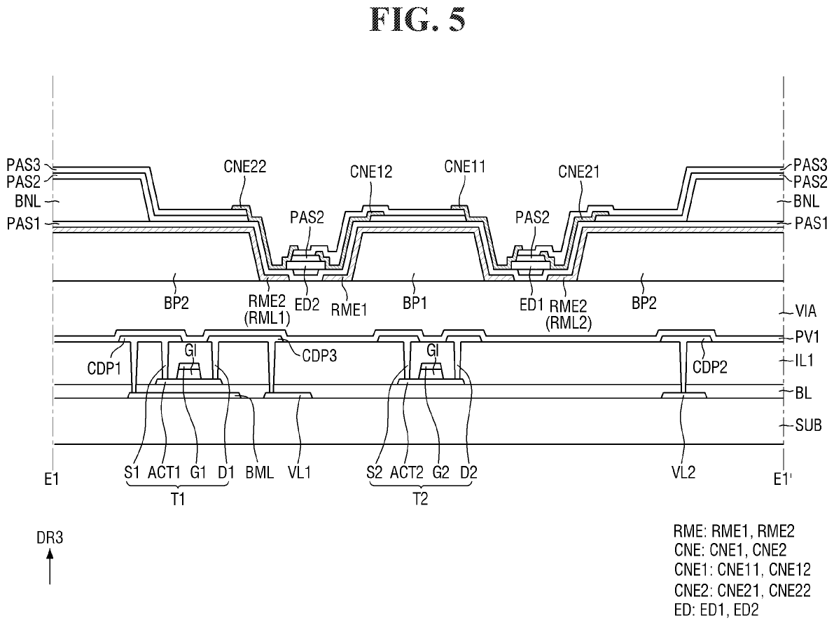

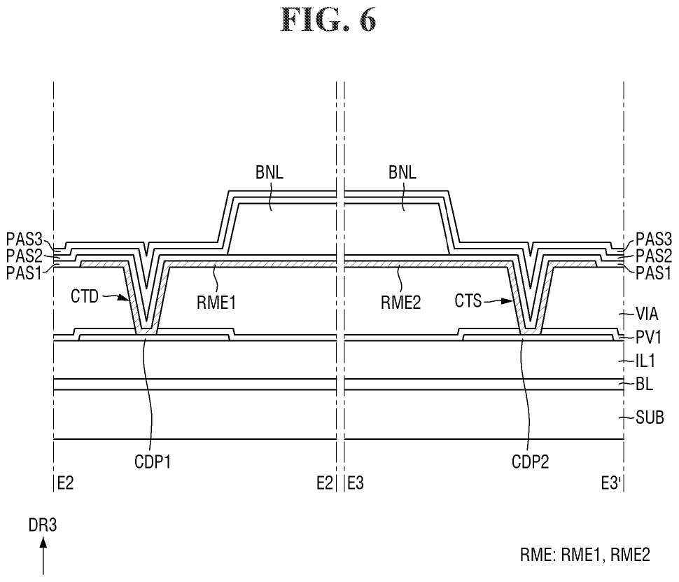

FIG. 5 is a cross-sectional view taken along the line E1-E1′ of FIG. 4. FIG. 6 is a cross-sectional view taken along the line E2-E2′ and taken along the line E3-E3′ of FIG. 4.

Referring to FIGS. 5 and 6 in addition to FIGS. 3 and 4, the display device 10 may include a first substrate SUB, and a semiconductor layer, a plurality of conductive layers, and a plurality of insulating layers, which are located on the first substrate SUB. In addition, the display device 10 may include a plurality of electrodes RME: RME1 and RME2, light emitting elements ED: ED1 and ED2, and connection electrodes CNE: CNE1 and CNE2. The semiconductor layer, the conductive layer, and the insulating layers may constitute a circuit layer of the display device 10, respectively.

The first substrate SUB may be an insulating substrate. The first substrate SUB may be made of an insulating material, such as glass, quartz, or a polymer resin. The first substrate SUB may be a rigid substrate, but may be a flexible substrate capable of being subjected to bending, folding, rolling, or the like. The first substrate SUB may include a display area DPA and a non-display area NDA surrounding the display area DPA, and the display area DPA may include a light emission area EMA and sub-areas SA1 and SA2 that are portions of a non-light emission area.

The first conductive layer may be located on the first substrate SUB. The first conductive layer may include a lower metal layer BML, a first voltage line VL1, and a second voltage line VL2. The lower metal layer BML is located to overlap a first active layer ACT1 of the first transistor T1. The lower metal layer BML may reduce or prevent light from being incident on the first active layer ACT1 of the first transistor T1, or may be electrically connected to the first active layer ACT1 to stabilize electrical characteristics of the first transistor T1. However, the lower metal layer BML may be omitted.

The high potential voltage (or first power voltage) transferred to the first electrode RME1 may be applied to the first voltage line VL1, and the low potential voltage (or second power voltage) transferred to the second electrode RME2 may be applied to the second voltage line VL2. The first voltage line VL1 may be electrically connected to the first transistor T1 through a conductive pattern (e.g., third conductive pattern CDP3) of the third conductive layer. The second voltage line VL2 may be electrically connected to the second electrode RME2 through a conductive pattern (e.g., second conductive pattern CDP2) of the third conductive layer.

The first voltage line VL1 and the second voltage line VL2 are illustrated as being located in the first conductive layer, but are not limited thereto. In some embodiments, the first voltage line VL1 and the second voltage line VL2 may be located in the third conductive layer and may be directly electrically connected to the first transistor T1 and the second electrode RME2, respectively.

A buffer layer BL may be located on the first conductive layer and the first substrate SUB. The buffer layer BL may be formed on the first substrate SUB to protect the transistors of the pixel PX from water permeated through the first substrate SUB vulnerable to moisture permeation, and may perform a surface planarization function.

The semiconductor layer is located on the buffer layer BL. The semiconductor layer may include the first active layer ACT1 of the first transistor T1 and a second active layer ACT2 of the second transistor T2. The first and second active layers ACT1 and ACT2 may be located to partially overlap a first gate electrode G1 and a second gate electrode G2 of the second conductive layer, which will be described later.

The semiconductor layer may include polycrystalline silicon, monocrystalline silicon, an oxide semiconductor, and the like. In one or more other embodiments, the semiconductor layer may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), or indium gallium zinc tin oxide (IGZTO).

One first transistor T1 is illustrated as being located in the subpixel SPXn of the display device 10, but the disclosure is not limited thereto, and the display device 10 may include a larger number of transistors.

A first gate insulating layer GI is located on the semiconductor layer in the display area DPA. The first gate insulating layer GI may serve as a gate insulating layer of each of the transistors T1 and T2. The first gate insulating layer GI is illustrated as being patterned together with the gate electrodes G1 and G2 of the second conductive layer, which will be described later, and is partially located between the second conductive layer and the active layers ACT1 and ACT2 of the semiconductor layer, but is not limited thereto. In some embodiments, the first gate insulating layer GI may be located entirely on the buffer layer BL.

The second conductive layer is located on the first gate insulating layer GI.

The second conductive layer may include a first gate electrode G1 of the first transistor T1 and a second gate electrode G2 of the second transistor T2. The first gate electrode G1 may be located to overlap a channel area of the first active layer ACT1 in a third direction DR3 that is a thickness direction, and the second gate electrode G2 may be located to overlap a channel area of the second active layer ACT2 in the third direction DR3 that is a thickness direction. In one or more embodiments, the second conductive layer may further include one electrode of the storage capacitor.

A first interlayer insulating layer IL1 is located on the second conductive layer. The first interlayer insulating layer IL1 may serve as an insulating layer between the second conductive layer and other layers located on the second conductive layer, and may protect the second conductive layer.

The third conductive layer is located on the first interlayer insulating layer IL1. The third conductive layer may include a plurality of conductive patterns CDP1, CDP2, and CDP3 and source electrodes S1 and S2 and drain electrodes D1 and D2 of the transistors T1 and T2. Some of the conductive patterns CDP1, CDP2, and CDP3 may electrically connect conductive layers or semiconductor layers of different layers to each other and serve as source/drain electrodes of the transistors T1 and T2.

The first conductive pattern CDP1 may be in contact with the first active layer ACT1 of the first transistor T1 through a contact hole that passes through the first interlayer insulating layer IL1. The first conductive pattern CDP1 may be in contact with the lower metal layer BML through a contact hole that passes through the first interlayer insulating layer IL1 and the buffer layer BL. The first conductive pattern CDP1 may serve as the first source electrode S1 of the first transistor T1. The first conductive pattern CDP1 may be electrically connected to the first electrode RME1 or the first connection electrode CNE1. The first transistor T1 may transfer the first power voltage applied from the first voltage line VL1 to the first electrode RME1 or the first connection electrode CNE1.

The second conductive pattern CDP2 may be in contact with the second voltage line VL2 through the contact hole that passes through the first interlayer insulating layer IL1 and the buffer layer BL. The second conductive pattern CDP2 may be electrically connected to the first electrode RME1 or the first connection electrode CNE1. The second voltage line VL2 may transfer the second power voltage to the second electrode RME2 or the second connection electrode CNE2.

The third conductive pattern CDP3 may be in contact with the first voltage line VL1 through the contact hole that passes through the first interlayer insulating layer IL1 and the buffer layer BL. In addition, the third conductive pattern CDP3 may be in contact with the first active layer ACT1 of the first transistor T1 through the contact hole that passes through the first interlayer insulating layer IL1. The third conductive pattern CDP3 may electrically connect the first voltage line VL1 to the first transistor T1, and may serve as the first drain electrode D1 of the first transistor T1.

The second source electrode S2 and the second drain electrode D2 may be in contact with the second active layer ACT2 of the second transistor T2 through the contact hole that passes through the first interlayer insulating layer IL1. The second transistor T2 may transfer a data signal to the first transistor T1, or may transfer an initialization signal.

A first passivation layer PV1 is located on the third conductive layer. The first passivation layer PV1 may serve as an insulating layer between the third conductive layer and the other layers, and may protect the third conductive layer.

The buffer layer BL, the first gate insulating layer GI, the first interlayer insulating layer IL1 and the first passivation layer PV1 may be formed of a plurality of inorganic layers that are alternately stacked. For example, the buffer layer BL, the first gate insulating layer GI, the first interlayer insulating layer IL1, and the first passivation layer PV1 may be formed of a double layer in which inorganic layers including at least one of silicon oxide (SiOₓ), silicon nitride (SiNₓ), or silicon oxynitride (SiOₓN_{y}) are stacked, or multiple layers in which the inorganic layers are alternately stacked, but are not limited thereto. The buffer layer BL, the first gate insulating layer GI, the first interlayer insulating layer IL1, and the first passivation layer PV1 may be made of one inorganic layer including the insulating material described above. Also, in some embodiments, the first interlayer insulating layer IL1 may be made of an organic insulating material, such as polyimide (PI).

A via layer VIA is located on the third conductive layer in the display area DPA. The via layer VIA may include an organic insulating material such as, for example, polyimide (PI), to compensate for a step difference caused by the lower conductive layers and to form a flat upper surface. However, in some embodiments, the via layer VIA may be omitted.

The display device 10 may include bank patterns BP1 and BP2, a plurality of electrodes RME: RME1 and RME2, a bank layer BNL, a plurality of light emitting elements ED, and a plurality of connection electrodes CNE: CNE1 and CNE2 as display element layers located on a via layer VIA. In addition, the display device 10 may include insulating layers PAS1, PAS2 and PAS3 located on the via layer VIA.

The plurality of bank patterns BP1 and BP2 may be located on the via layer VIA. For example, the bank patterns BP1 and BP2 may be directly located on the via layer VIA, and at least a portion of the bank patterns BP1 and BP2 may have a protruded structure based on the upper surface of the via layer VIA. The protruded portions of the bank patterns BP1 and BP2 may have sides inclined or bent with a curvature (e.g., predetermined curvature), and light emitted from the light emitting element ED may be reflected by the electrode RME located on the bank patterns BP1 and BP2 and may be emitted in an upper direction of the via layer VIA. Unlike the shown example, an outer surface of the bank patterns BP1 and BP2 on a cross-sectional view may have a shape curved with a curvature (e.g., predetermined curvature), for example, a semi-circular or semi-elliptical shape. The bank patterns BP1 and BP2 may include, but are not limited to, an organic insulating material, such as polyimide (PI).

The plurality of electrodes RME: RME1 and RME2 may be located on the bank patterns BP1 and BP2 and the via layer VIA. For example, the first electrode RME1 and the second electrode RME2 may be located on the inclined sides of the bank patterns BP1 and BP2. For example, a width of each of the first electrode RME1 and the second electrode RME2, which is measured in the second direction DR2, may be greater than that of the bank patterns BP1 and BP2, and the first electrode RME1 and the second electrode RME2 may cover the inclined sides of the first bank pattern BP1 and the second bank pattern BP2. The second electrode RME2 is illustrated as covering one side of the second bank pattern BP2, which is located in the light emission area EMA, but the second electrode RME2 may also cover the other side of the second bank pattern BP2 located in the light emission area EMA of another adjacent subpixel SPXn. The first electrode RME1 located on the first bank pattern BP1 may be the first electrode body portion RMB1, and the second electrode RME2 located on the second bank pattern BP2 may be the second electrode body portion RMB2.

An interval between the first electrode RME1 and the second electrode RME2, which are spaced apart from each other in the second direction DR2, may be narrower than that between the bank patterns BP1 and BP2. As at least a portion of the first electrode RME1 and the second electrode RME2 may be located directly on the via layer VIA and thus may be located on the same plane.

The light emitting elements ED located between the bank patterns BP1 and BP2 emit light in both end directions, and the emitted light may be directed to the electrode RME located on the bank patterns BP1 and BP2. Each electrode RME may have a structure in which a portion located on the bank patterns BP1 and BP2 may reflect light emitted from the light emitting element ED. The first electrode RME1 and the second electrode RME2 may be located to cover at least one side of the bank patterns BP1 and BP2 to reflect the light emitted from the light emitting element ED.

Each of the electrodes RME may be in contact with the third conductive layer through the electrode contact holes CTD and CTS in the sub-areas SA1 and SA2, respectively. The first electrode contact hole CTD may be formed in the first sub-area SA1, and the second electrode contact hole CTS may be formed in the second sub-area SA2. The first electrode RME1 located in the first electrode contact hole CTD may be the first electrode extension portion RMS1, and the second electrode RME2 located in the second electrode contact hole CTS may be the second electrode extension portion RMS2.

The first electrode RME1 may be in contact with the first conductive pattern CDP1 through a first electrode contact hole CTD that passes through the via layer VIA and the first passivation layer PV1. The second electrode RME2 may be in contact with the second conductive pattern CDP2 through a second electrode contact hole CTS that passes through the via layer VIA and the first passivation layer PV1. The first electrode RME1 may be electrically connected to the first transistor T1 through the first conductive pattern CDP1 to apply the first power voltage thereto, and the second electrode RME2 may be electrically connected to the second voltage line VL2 through the second conductive pattern CDP2 to apply the second power voltage thereto, but the disclosure is not limited thereto. In one or more other embodiments, the electrodes RME1 and RME2 might not be electrically connected to the voltage lines VL1 and VL2 of the third conductive layer, and a connection electrode CNE, which will be described later, may be directly connected to the third conductive layer.

The plurality of electrodes RME may include a conductive material having high reflectance. For example, the electrodes RME may include a metal, such as silver (Ag), copper (Cu) and aluminum (Al) or an alloy containing aluminum (Al), nickel (Ni), lanthanum (La), etc. or may have a structure in which a metal layer, such as titanium (Ti), molybdenum (Mo) and niobium (Nb) and the alloy are stacked. In some embodiments, the electrodes RME may be a double layer or multiple layers in which an alloy containing aluminum (Al) and at least one metal layer of titanium (Ti), molybdenum (Mo) or niobium (Nb) are stacked.

Without limitation to the above example, each of the electrodes RME may further include a transparent conductive material. For example, each electrode RME may include a material, such as ITO, IZO and ITZO. In some embodiments, each of the electrodes RME may have a structure in which one or more layers of a transparent conductive material and a metal layer having high reflectance are stacked or may be formed as a single layer including the transparent conductive material and the metal layer. For example, each electrode RME may have a stacked structure, such as ITO/Ag/ITO/, ITO/Ag/IZO or ITO/Ag/ITZO/IZO. The electrodes RME may be electrically connected to the light emitting elements ED and may reflect some of the light emitted from the light emitting elements ED in an upper direction of the first substrate SUB.

The first insulating layer PAS1 may be located on the via layer VIA and the plurality of electrodes RME. The first insulating layer PAS1 may include an insulating material to protect the plurality of electrodes RME, and at the same time may mutually insulate the different electrodes RME. The first insulating layer PAS1 is located to cover the electrodes RME before the bank layer BNL is formed, thereby reducing or preventing the likelihood of the electrodes RME being damaged in the process of forming the bank layer BNL. In addition, the first insulating layer PAS1 may reduce or prevent the likelihood of the light emitting element ED located thereon being damaged due to direct contact with other members.

In one or more embodiments, the first insulating layer PAS1 may be stepped such that a portion of an upper surface is recessed between the electrodes spaced apart from each other in the second direction DR2. The light emitting element ED may be located on an upper surface where the step difference of the first insulating layer PAS1 is formed, and a space may be formed between the light emitting element ED and the first insulating layer PAS1.

The bank layer BNL may be located on the first insulating layer PAS1. The bank layer BNL includes a portion extended in the first direction DR1 and the second direction DR2, and may surround each of the subpixels SPXn. The bank layer BNL may distinguish the light emission area EMA from the sub-area SA while surrounding the light emission area EMA and the sub-area SA of each subpixel SPXn, and may distinguish the display area DPA from the non-display area NDA while surrounding the outermost periphery of the display area DPA.

The bank layer BNL may have a height (e.g., predetermined height) that is similar to that of the bank patterns BP1 and BP2. A portion of the bank layer BNL may include a portion overlapped with the bank patterns BP1 and BP2 and the electrodes RME1 and RME2. In some embodiments, an upper surface of the bank layer BNL may be higher than the bank patterns BP1 and BP2, and its thickness may be equal to or greater than that of the bank patterns BP1 and BP2. The bank layer BNL may reduce or prevent the likelihood of ink overflowing to the subpixel SPXn adjacent thereto in an inkjet printing process of a manufacturing process of the display device 10. The bank layer BNL may include an organic insulating material, such as polyimide or polyamide.

The light emitting elements ED may be located in the light emission area EMA. The light emitting elements ED may be located on the first insulating layer PAS1 between the bank patterns BP1 and BP2. The light emitting element ED2 may be located such that a portion extended in one direction is to be substantially parallel with the upper surface of the first substrate SUB. As described below, the light emitting elements ED may include a plurality of semiconductor layers located along the extended direction, and the plurality of semiconductor layers may be sequentially located along a direction parallel with the upper surface of the first substrate SUB, but the disclosure is not limited thereto. When the light emitting element ED has another structure, the plurality of semiconductor layers may be located in a direction that is substantially perpendicular to the first substrate SUB.

The light emitting elements ED located in the respective subpixels SPXn may emit light having different wavelength bands depending on the material of the semiconductor layer, but are not limited thereto. The light emitting elements ED located in the respective subpixels SPXn may include semiconductor layers of the same material to emit light of the same color.

The light emitting elements ED may be located on different electrodes RME between different bank patterns BP1 and BP2. The first light emitting element ED1 may be located between the first bank pattern BP1 and the second bank pattern BP2 so that respective ends thereof may be located on the first electrode body portion RMB1 of the first electrode RME1, and the second electrode body portion RMB2 of the second electrode RME2. Based on the first subpixel SPX1, the first light emitting element ED1 may be located on the second electrode line RML2 of the second electrode RME2, and may be located on the right side of the first bank pattern BP1 in the light emission area EMA. The second light emitting element ED2 may be located between the second bank pattern BP2 and the first bank pattern BP1 so that respective ends thereof may be located on the first electrode body portion RMB1 of the first electrode RME1, and the second electrode body portion RMB2 of the second electrode RME2. Based on the first subpixel SPX1, the second light emitting element ED2 may be located on the first electrode line RML1 of the second electrode RME2, and may be located on the left side of the first bank pattern BP1 in the light emission area EMA.

The light emitting elements ED may be in contact with the connection electrodes CNE: CNE1, CNE2 and CNE3, and thus may be electrically connected to the conductive layers below the electrodes RME and the via layer VIA, and may emit light of a corresponding wavelength band as an electrical signal is applied thereto.

The second insulating layer PAS2 may be located on the plurality of light emitting elements ED, the first insulating layer PAS1, and the bank layer BNL. The second insulating layer PAS2 includes a pattern portion extended in the first direction DR1 between the bank patterns BP1 and BP2, and located on the plurality of light emitting elements ED. The pattern portion is located to partially surround an outer surface of the light emitting element ED, and may not cover both sides or both ends of the light emitting element ED. The pattern portion may form a linear or island shaped pattern within each subpixel SPXn on the plan view. The pattern portion of the second insulating layer PAS2 may protect the light emitting elements ED, and at the same time, may fix the light emitting elements ED in the manufacturing process of the display device 10. Also, the second insulating layer PAS2 may be located to fill a space between the light emitting element ED and the first insulating layer below the light emitting element ED. In addition, a portion of the second insulating layer PAS2 may be located on the bank layer BNL and in the sub-areas SA.

The plurality of connection electrodes CNE: CNE1 and CNE2 may be located on the electrodes RME and the bank patterns BP1 and BP2.

The first connection electrode CNE1 may be located on the first electrode RME1 and the first bank pattern BP1. The first sub-connection electrode CNE11 of the first connection electrode CNE1 may be located on a right upper portion of the first electrode RME1 and the first bank pattern BP1. The second sub-connection electrode CNE12 may be located on a left upper portion of the first electrode RME1 and the first bank pattern BP1.

The second connection electrode CNE2 may be located on the second electrode RME2 and the second bank pattern BP2. The third sub-connection electrode CNE21 of the second connection electrode CNE2 is the second electrode RME2 located on the right side of the first electrode RME1, and may be located on the second electrode line RML2 and the second bank pattern BP2. The fourth sub-connection electrode CNE22 is the second electrode RME2 located on the left side of the first electrode RME1, and may be located on the first electrode line RML1 and the second bank pattern BP2.

Each of the first and second connection electrodes CNE1 and CNE2 may be located on the second insulating layer PAS2, and may be in contact with the light emitting elements ED. The first connection electrode CNE1 may be in contact with first ends of the light emitting elements ED1 and ED2. The first sub-connection electrode CNE11 may be in contact with the first end of the first light emitting element ED1, and the second sub-connection electrode CNE12 may be in contact with the first end of the second light emitting element ED2. The second connection electrode CNE2 may be in contact with second ends of the light emitting elements ED1 and ED2. The third sub-connection electrode CNE21 may be in contact with the second end of the first light emitting element ED1, and the fourth sub-connection electrode CNE22 may be in contact with the second end of the second light emitting element ED2.

The connection electrodes CNE may include a conductive material. For example, the connection electrodes CNE may include ITO, IZO, ITZO, Al, etc. For example, the connection electrode CNE include a transparent conductive material, and light emitted from the light emitting element ED may be emitted by transmitting the connection electrode CNE.

The third insulating layer PAS3 is located on the connection electrodes CNE1 and CNE2 and the second insulating layer PAS2. The third insulating layer PAS3 may insulate the first connection electrode CNE1 and the second connection electrode CNE2 from each other such that the first connection electrode CNE1 and the second connection electrode CNE2 are not directly in contact with each other.

Each of the first insulating layer PAS1, the second insulating layer PAS2, and the third insulating layer PAS3 may include an inorganic insulating material or an organic insulating material. For example, each of the first insulating layer PAS1, the second insulating layer PAS2, and the third insulating layer PAS3 may include an inorganic insulating material. In another example, the first insulating layer PAS1 and the third insulating layer PAS3 may include an inorganic insulating material, and the second insulating layer PAS2 may include an organic insulating material. Each or at least one of the first insulating layer PAS1, the second insulating layer PAS2, or the third insulating layer PAS3 may be formed in a structure in which a plurality of insulating layers are alternately or repeatedly stacked. In one or more embodiments, when each of the first insulating layer PAS1, the second insulating layer PAS2, and the third insulating layer PAS3 includes an inorganic insulating material, each of them may be any one of silicon oxide (SiOₓ), silicon nitride (SiNₓ), and silicon oxynitride (SiOₓN_{y}). When the first insulating layer PAS1, the second insulating layer PAS2, and the third insulating layer PAS3 include an organic insulating material, each of them may be an acrylic resin, a urethane-based resin, an epoxy-based resin, or a polyimide-based resin.

The first insulating layer PAS1, the second insulating layer PAS2, and the third insulating layer PAS3 may be made of the same material or a portion of the first insulating layer PAS1, the second insulating layer PAS2, and the third insulating layer PAS3 may be made of the same material, and the other portion thereof may be made of different materials, or, instead, all of the first to third insulating layers may be made of their respective materials different from one another.

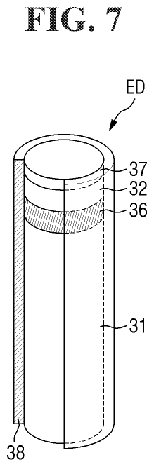

FIG. 7 is a schematic view illustrating a light emitting element according to one or more embodiments.

Referring to FIG. 7, the light emitting element ED may be a light emitting diode, and for example, the light emitting element ED may be an inorganic light emitting diode made of an inorganic material with a size of a nano-meter to a micro-meter. The light emitting element ED may be aligned between two electrodes having polarities when an electric field is formed in a corresponding direction between the two electrodes facing each other.

The light emitting element ED according to one or more embodiments may have a shape extended in one direction. The light emitting element ED may have a cylindrical shape, a rod shape, a wire shape or a tube shape, but is not limited thereto. The light emitting element ED may have a polygonal pillar shape, such as a cube, a cuboid and a hexagonal pillar, or may have various shapes, such as a shape extended in one direction, having an outer surface that is partially inclined.

The light emitting element ED may include a semiconductor layer doped with any conductivity type (e.g., p-type or n-type) impurities. The semiconductor layer may emit light of a corresponding wavelength band as an electrical signal applied from an external power source is transferred thereto. The light emitting element ED may include a first semiconductor layer 31, a second semiconductor layer 32, a light emitting layer 36, an electrode layer 37, and an insulating layer 38.

The first semiconductor layer 31 may be an n-type semiconductor. The first semiconductor layer 31 may include a semiconductor material having a formula of AlₓGa_{y}In_{1-x-y}N (0≤x≤1, 0≤y≤1, 0≤x+y≤1). For example, the first semiconductor layer 31 may be any one or more of AlGaInN, GaN, AlGaN, InGaN, AlN and InN, which are doped with n-type dopants. The n-type dopants doped in the first semiconductor layer 31 may be Si, Ge, Sn, Se, etc.

The second semiconductor layer 32 is located on the first semiconductor layer 31 with the light emitting layer 36 interposed therebetween. The second semiconductor layer 32 may be a p-type semiconductor, and may include a semiconductor material having a chemical formula of AlₓGa_{y}In_{1-x-y}N (0≤x≤1, 0≤y≤1, 0≤x+y≤1). For example, the second semiconductor layer 32 may be any one or more of AlGaInN, GaN, AlGaN, InGaN, AlN and InN, which are doped with p-type dopants. The p-type dopants doped in the second semiconductor layer 32 may be Mg, Zn, Ca, Ba, etc.

The first semiconductor layer 31 and the second semiconductor layer 32 are shown as being formed of a single layer, but are not limited thereto. The first semiconductor layer 31 and the second semiconductor layer 32 may further include a larger number of layers, such as a clad layer or a tensile strain barrier reducing (TSBR) layer, depending on the material of the light emitting layer 36. For example, the light emitting element ED may further include another semiconductor layer located between the first semiconductor layer 31 and the light emitting layer 36 or between the second semiconductor layer 32 and the light emitting layer 36. The semiconductor layer located between the first semiconductor layer 31 and the light emitting layer 36 may be any one or more of AlGaInN, GaN, AlGaN, InGaN, AlN, InN, and SLs, which are doped with n-type dopants. The semiconductor layer located between the second semiconductor layer 32 and the light emitting layer 36 may be one or more of AlGaInN, GaN, AlGaN, InGaN, AlN, and InN, which are doped with p-type dopants.

The light emitting layer 36 is located between the first semiconductor layer 31 and the second semiconductor layer 32. The light emitting layer 36 may include a single or multiple quantum well structure material. When the light emitting layer 36 includes a material of a multiple quantum well structure, a plurality of quantum layers and a plurality of well layers may be alternately stacked. The light emitting layer 36 may emit light by combination of electron-hole pairs in accordance with electrical signals applied through the first semiconductor layer 31 and the second semiconductor layer 32. The light emitting layer 36 may include a material, such as AlGaN, AlGaInN and InGaN. For example, when the light emitting layer 36 has a stacked structure of quantum layers and well layers, which are alternately stacked in a multiple quantum well structure, the quantum layer may include a material, such as AlGaN or AlGaInN, and the well layer may include a material, such as GaN or AlInN.

The light emitting layer 36 may have a structure in which a semiconductor material having a big band gap energy and semiconductor materials having a small band gap energy are alternately stacked, and may include group-III or group-V semiconductor materials depending on a wavelength band of light that is emitted. The light emitting layer 36 may emit light of a red or green wavelength band, as the case may be, without being limited to light of a blue wavelength band.

The electrode layer 37 may be an ohmic connection electrode, but is not limited thereto. The electrode layer 37 may be a Schottky connection electrode. The light emitting element ED may include at least one electrode layer 37. The light emitting element ED includes one or more electrode layers 37, but is not limited thereto. The electrode layer 37 may be omitted.

The electrode layer 37 may reduce resistance between the light emitting element ED and an electrode or a connection electrode when the light emitting element ED is electrically connected with the electrode or the connection electrode in the display device 10. The electrode layer 37 may include a metal having conductivity. For example, the electrode layer 37 may include at least one of Al, Ti, In, Au, Ag, ITO, IZO or ITZO.

The insulating layer 38 is located to surround outer surfaces of the plurality of semiconductor layers and electrode layers. For example, the insulating layer 38 may be located to surround at least an outer surface of the light emitting layer 36, and may be formed to expose both ends in a longitudinal direction of the light emitting element ED. Also, the insulating layer 38 may be formed with a rounded upper surface on a section in an area adjacent to at least one end of the light emitting element ED.

The insulating layer 38 may include materials having insulation property, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ) or titanium oxide (TiOₓ). The insulating layer 38 is illustrated as being formed of a single layer, but is not limited thereto. In some embodiments, the insulating layer 38 may be formed of a multi-layered structure in which multiple layers are stacked.

The insulating layer 38 may serve to protect the semiconductor layers and the electrode layers of the light emitting element ED. The insulating layer 38 may reduce or prevent the likelihood of an electrical short that may occur in the light emitting layer 36 when the light emitting element ED is directly in contact with the electrode to which the electrical signal is transferred. In addition, the insulating layer 38 may reduce or prevent deterioration of the light emitting efficiency of the light emitting element ED.

Also, an outer surface of the insulating layer 38 may be surface-treated. The light emitting element ED may be aligned by being sprayed onto the electrode in a state that it is dispersed in an ink (e.g., predetermined ink). The surface of the insulating layer 38 may be hydrophobic-treated or hydrophilic-treated, so that the light emitting element ED may be maintained to be dispersed in the ink without being condensed with another light emitting element ED adjacent thereto.

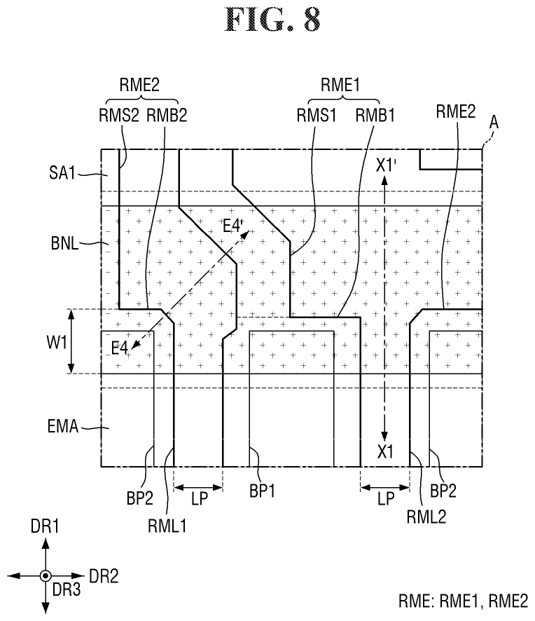

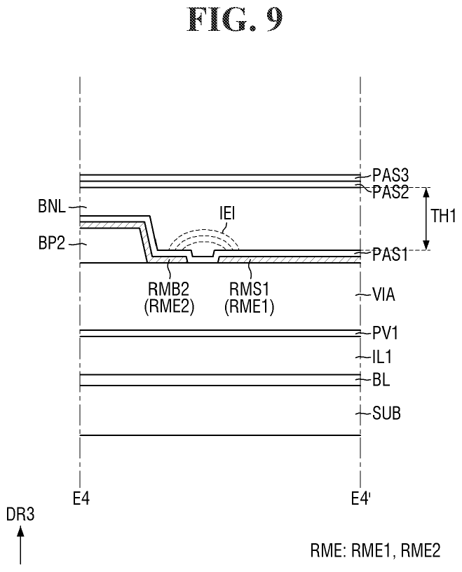

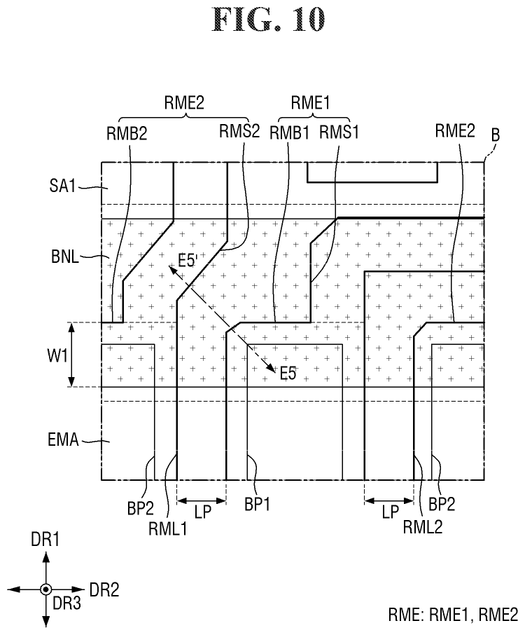

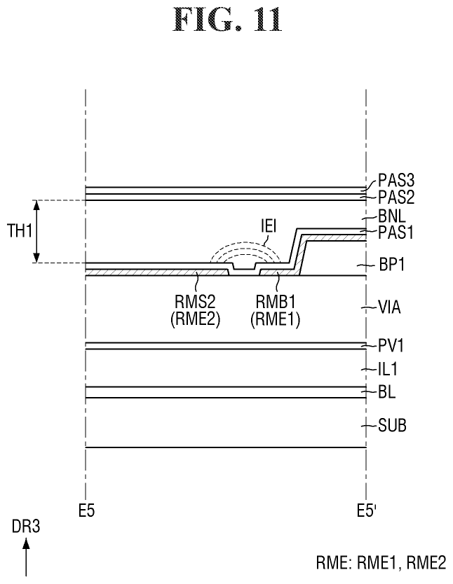

FIG. 8 is an enlarged plan view illustrating area A of FIG. 3. FIG. 9 is a cross-sectional view taken along the line E4-E4′ of FIG. 8. FIG. 10 is an enlarged plan view illustrating area B of FIG. 3. FIG. 11 is a cross-sectional view taken along the line E5-E5′ of FIG. 10.

Referring to FIGS. 8 to 11, the bank layer BNL of the display device 10 according to one or more embodiments may overlap the electrode body portions RMB1 and RMB2 in the third direction DR3 as much as a first width W1. FIGS. 8 and 9 illustrate that the bank layer BNL is located to cover the second electrode body portion RMB2 and the first electrode extension portion RMS1, and FIGS. 10 and 11 illustrate that the bank layer BNL is located to cover the first electrode body portion RMB1 and the second electrode extension portion RMS2.

The bank layer BNL may overlap the electrode extension portions RMS1 and RMS2, and may be located to overlap the electrode body portions RMB1 and RMB2 as much as the first width W1. For example, the first width W1 may be about 7 um or more. The bank layer BNL may be located to cover or overlap the electrode body portions RMB1 and RMB2 as much as the first width W1, thereby deteriorating an electric field IEI generated at one end of the electrode body portions RMB1 and RMB2 and one end of the electrode extension portions RMS1 and RMS2.

In accordance with one or more embodiments, the electrode extension portions RMS1 and RMS2 at least partially bent, having a portion extended in a diagonal direction inclined from the first direction DR1 or the second direction DR2 may be located in the sub-areas SA1 and SA2 that include contact holes (e.g., electrode contact holes CTS and CTD) for transferring an electrical signal to the plurality of subpixel SPXn. One end of the electrode extension portions RMS1 and RMS2 and one end of the electrode body portions RMB1 and RMB2 may be close to each other above or below the light emission area EMA. When the electric field IEI is formed between the first electrode RME1 and the second electrode RME2, to which different signals are applied, above or below the light emission area EMA where one end of the electrode extension portions RMS1 and RMS2 and one end of the electrode body portions RMB1 and RMB2 are close to each other, the light emitting elements ED may be agglomerated in the upper and lower portions of the light emission area EMA. That is, the light emitting elements ED may be located outside an alignment area LP in which the light emitting elements ED are aligned. In this case, the alignment area LP may be an area or path in which the light emitting elements ED are aligned, and may be an area included in the light emission area EMA partitioned by the bank layer BNL. The alignment area LP may correspond to a portion between the first electrode RME1 and the second electrode RME2 in the light emission area EMA.

The bank layer BNL may be located to overlap the electrode body portions RMB1 and RMB2 and the electrode extension portions RMS1 and RMS2 to cover one end of the electrode body portions RMB1 and RMB2 and one end of the electrode extension portions RMS1 and RMS2. Therefore, the bank layer BNL may deteriorate the electric field generated at one end of the electrode body portions RMB1 and RMB2 and one end of the electrode extension portions RMS1 and RMS2.

The bank layer BNL may include an organic insulating material as described above. The bank layer BNL may include an organic insulating material having a dielectric constant of about 2 to about 4, for example, polyimide (PI) or polyamide (PA). The bank layer BNL may include an organic material having a relatively high dielectric constant, and thus may serve as a dielectric for deteriorating the electric field IEI generated from the electrode body portions RMB1 and RMB2 and the electrode extension portions RMS1 and RMS2. The bank layer BNL may reduce or prevent the likelihood of the light emitting elements ED being agglomerated in the upper or lower portion of the light emission area EMA outside the alignment area LP of the light emission area EMA.

For example, referring to FIGS. 8 and 9, the first electrode extension portion RMS1 may include a portion bent in a diagonal direction inclined toward the second electrode body portion RMB2 from the first direction DR1. When the bank layer BNL overlapped with the first electrode extension portion RMS1 and the second electrode body portion RMB2, which are adjacent to each other, is located on one end of the first electrode extension portion RMS1 and one end of the second electrode body portion RMB2, the likelihood of the electric field IEI being formed between one end of the first electrode extension portion RMS1, to which the first power voltage is applied, and one end of the second electrode body portion RMB2, to which the second power voltage is applied, may be reduced or prevented. Therefore, the bank layer BNL may reduce or prevent the likelihood of the light emitting elements ED being agglomerated in the upper and lower portions of the light emission area EMA outside the alignment area LP by the electric field IEI. Therefore, a dark spot of the display device 10 may be prevented from being generated or may be less generated.

Referring to FIGS. 10 and 11, the second electrode extension portion RMS2 may include a portion bent in a diagonal direction inclined toward the first electrode body portion RMB1 from the first direction DR1. When the bank layer BNL overlapped with the second electrode extension portion RMS2 and the first electrode body portion RMB1, which are adjacent to each other, is located on one end of the second electrode extension portion RMS2 and one end of the first electrode body portion RMB1, the likelihood of the electric field IEI being formed between the second electrode extension portion RMS2 and the first electrode body portion RMB1, to which different voltages are applied, may be reduced or prevented. Therefore, the bank layer BNL may reduce or prevent the likelihood of the light emitting elements ED being agglomerated in the upper and lower portions of the light emission area EMA outside the alignment area LP by the electric field IEI.

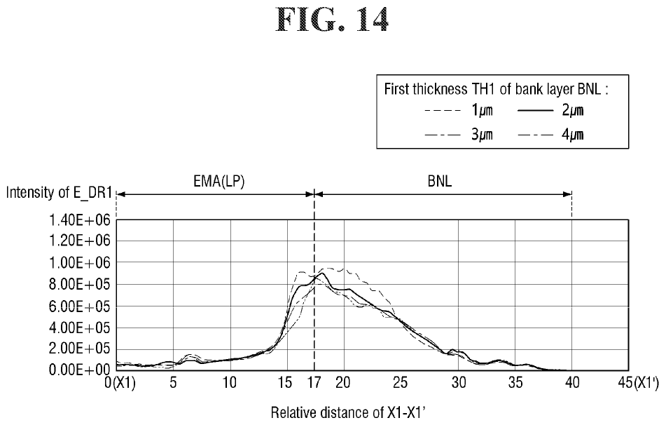

The bank layer BNL may be located on the electrodes RME1 and RME2, the first insulating layer PAS1, and the bank patterns BP1 and BP2 with a thickness (e.g., predetermined thickness). The bank layer BNL may have a constant height. The bank layer BNL may include a first area that does not overlap the bank patterns BP1 and BP2, and a second area that overlaps the bank patterns BP1 and BP2. Because the upper surface of the bank layer BNL is generally flat, the thickness of the bank layer BNL may be different in the first area and the second area. The bank layer BNL may have a first thickness TH1 in the first area, and may have a second thickness in the second area. The first thickness TH1 may be the maximum thickness of the bank layer BNL, and the second thickness may be the minimum thickness of the bank layer BNL, but the disclosure is not limited thereto. The first thickness TH1 of the bank layer BNL may be about 1 um or more, and for example, when the first thickness TH1 of the bank layer BNL is about 2 um or more, the electric field IEI between the electrodes RME1 and RME2 may be effectively reduced. This will be described in detail with reference to FIG. 14. The second thickness of the bank layer BNL may be less than the first thickness TH1. For example, the second thickness of the bank layer BNL may be about 2 um or less. The bank layer BNL may have different thicknesses in the first area and the second area to compensate for a step difference between the first area and the second area, but is not limited thereto, and the thickness of the bank layer BNL may be the same in the first area and the second area, and an upper surface of the first area may be higher than that of the second area.

Meanwhile, the first thickness TH1 or the second thickness of the bank layer BNL may be thicker than the insulating layers containing an inorganic insulating material. For example, when the first insulating layer PAS1 includes an inorganic insulating material, the first thickness TH1 or the second thickness of the bank layer BNL may be thicker than the first insulating layer PAS1.

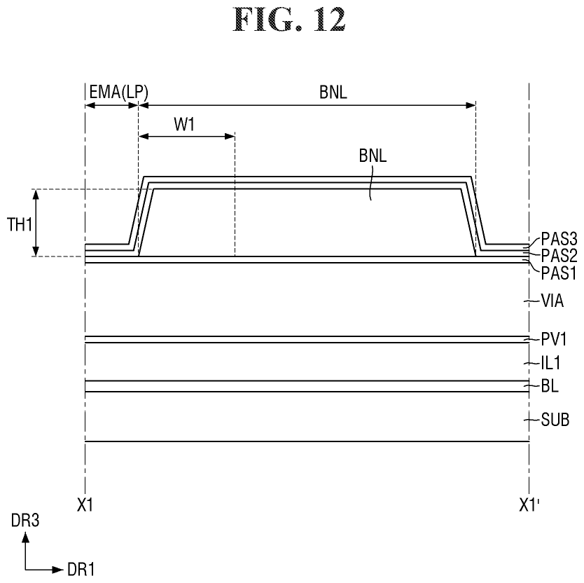

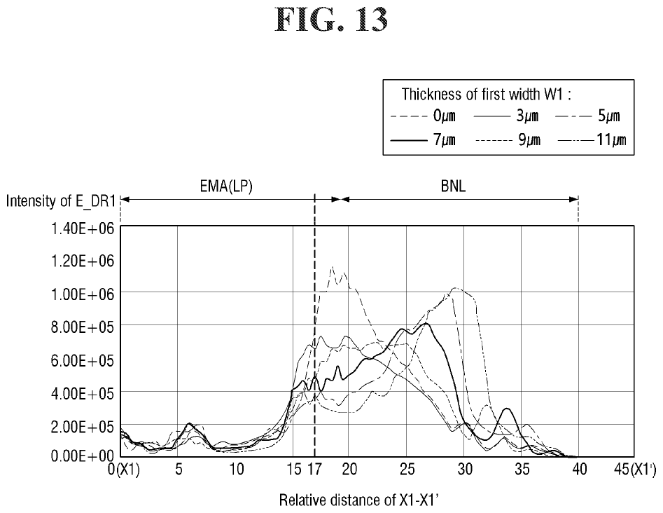

Hereinafter, an intensity change of an electric field E_DR1 in the first direction DR1 according to the first width W1 of the bank layer BNL will be described with reference to FIGS. 12 and 13. Also, the intensity change of the electric field E_DR1 in the first direction DR1 according to the first thickness TH1 of the bank layer BNL will be described with reference to FIGS. 12 and 13.

FIG. 12 is a cross-sectional view taken along the line X1-X1′ of FIG. 8. FIG. 13 is a graph illustrating intensity of an electric field in a first direction according to a first width of FIGS. 8 and 12. FIG. 12 shows a portion of the alignment area LP, which is an area in which the first electrode RME1 and the second electrode RME2 are not located in the light emission area EMA of FIG. 8, a boundary (e.g., upper end of the light emission area EMA) of the light emission area EMA and the bank layer BNL, and both ends of the bank layer BNL. The first width W1 of the bank layer BNL refers to a length of an area where the electrodes RME1 and RME2 overlap the bank layer BNL in FIG. 8. The first thickness TH1 of the bank layer BNL refers to the maximum thickness in the first area where the bank layer BNL does not overlap the bank patterns BP1 and BP2. Referring to FIGS. 8 and 12 together with FIG. 13, the bank layer BNL may be located to overlap the electrode body portions RMB1 and RMB2 as much as the first width W1. X-axis represents a relative position from X1 to X1′ of FIGS. 8 and 12, and Y-axis represents the intensity of the electric field E_DR1 in the first direction DR1 between the electrode extension portions RMS1 and RMS2 and the electrode body portions RMB1 and RMB2, to which different signals are applied. The graph of FIG. 13 shows the intensity (Y-axis) of the electric field E_DR1 according to the position (X-axis) when the first width W1 is about 0 um, 3 um, 5 um, 7 um, 9 um, and 11 um. Based on 17 of the X-axis, X1 to 17 are the electric field E_DR1 of the alignment area LP inside the light emission area EMA, and 17 to X1′ are the electric field E_DR1 of the bank layer BNL outside the light emission area EMA. In FIG. 12, the intensity of the electric field E_DR1 in the case that the X-axis is 17 refers to the electric field intensity at the boundary between the light emission area EMA (or alignment area LP) and the bank layer BNL. In other words, Because the intensity of the electric field E_DR1 when the X-axis is 17 refers to the intensity of the electric field at the upper end or the lower end of the light emission area EMA, the change in the electric field E_DR1 when the X-axis is 17 will be mainly described in detail.

When the first width W1 is 0 μm, that is, when the bank layer BNL does not overlap the electrode body portions RMB1 and RMB2, the intensity of the electric field E_DR1 above and below the light emission area EMA may be approximately 1.8×10⁶ V/m.

When the first width W1 is increased from 3 um to 11 um, the electric field E_DR1 at the upper end of the light emission area EMA and the electric field E_DR1 at the lower end of the light emission area EMA may be reduced (hereinafter, the electric field E_DR1 at the upper end of the light emission area EMA and the electric field E_DR1 at the lower end of the light emission area EMA are used as the same term as the electric field E_DR1 of the upper and lower portions). For example, when the first width W1 is about 7 um or more, the electric field E_DR1 may be reduced to reach about 4×10⁵ V/m. When the electric field E_DR1 is about 4×10⁵ V/m or less, the influence of the electric field of the upper and lower portions of the light emission area EMA on the alignment area LP may be small enough to disregard an electric field value thereof. That is, Because the electric field formed in the alignment area LP is approximately 4×10⁶ V/m, it may be about 10 times higher than the electric field E_DR1 of the upper and lower portions of the light emission area EMA. In this case, in the process of aligning the light emitting element ED, because the light emitting element ED may be stably aligned in the alignment area LP without being affected by the electric field E_DR1 of the upper and lower portions of the light emission area EMA, the likelihood of the light emitting element ED being agglomerated in the upper and lower portions of the light emission area EMA may be reduced or prevented. Therefore, when the bank layer BNL is located to overlap the electrode body portions RMB1 and RMB2 as much as about 7 um or more, the light emitting element ED may be stably aligned in the alignment area LP without being affected by the electric field E_DR1 of the upper and lower portions of the light emission area EMA.

FIG. 14 is a graph illustrating intensity of an electric field in a first direction according to a first thickness of a bank layer of FIGS. 8 and 12.

Referring to FIGS. 8 and 12 together with FIG. 14, the bank layer BNL may have a first thickness TH1 in a first area that does not overlap the bank patterns BP1 and BP2. X-axis represents a relative position from X1 to X1′ of FIGS. 8 and 12, and Y-axis represents intensity of the electric field E_DR1 in the first direction DR1 between the electrode extension portions RMS1 and RMS2 and the electrode body portions RMB1 and RMB2, to which different signals are applied. The graph of FIG. 14 shows the intensity (Y-axis) of the electric field E_DR1 according to the position (X-axis) when the first thickness TH1 is 1 um, 2 um, 3 um, and 4 um, respectively. When the X-axis is 17, the intensity of the electric field E_DR1 refers to the intensity of the electric field of the upper end of the light emission area EMA, which is the boundary between the alignment area LP and the bank layer BNL, and thus the following described will be made based on the intensity of the electric field E_DR1.

As the first thickness TH1 of the bank layer BNL becomes thicker, the electric field generated at one end of the electrodes RME1 and RME2 may be reduced. As the first thickness TH1 of the bank layer BNL becomes thicker, the electric field E_DR1 generated at one end of the electrode body portions RMB1 and RMB2 and one end of the electrode extension portions RMS1 and RMS2 may be reduced. For example, in FIG. 9, as the first thickness TH1 of the bank layer BNL becomes thicker, the electric field generated at one end of the second electrode body portion RMB2 and one end of the first electrode extension portion RMS1 may be reduced. For another example, in FIG. 11, as the first thickness TH1 of the bank layer BNL becomes thicker, the electric field generated at one end of the first electrode body portion RMB1 and one end of the second electrode extension portion RMS2 may be reduced.

Referring to FIG. 13, the first thickness TH1 of the bank layer BNL may be 1 um or more, and for example, when the first thickness TH1 of the bank layer BNL is 2 um or more, a reduction width of the intensity of the electric field E_DR1 between the electrodes RME1 and RME2 may be increased. The bank layer BNL may have a thickness that is relatively thick within the range that the electric field of the alignment area LP for aligning the light emitting element ED is not deteriorated.

The graphs of FIGS. 13 and 14 may be applied to the electric field intensity of the light emission area EMA (or alignment area LP) and the bank layer BNL of FIGS. 10 and 11, and thus their description will be omitted.

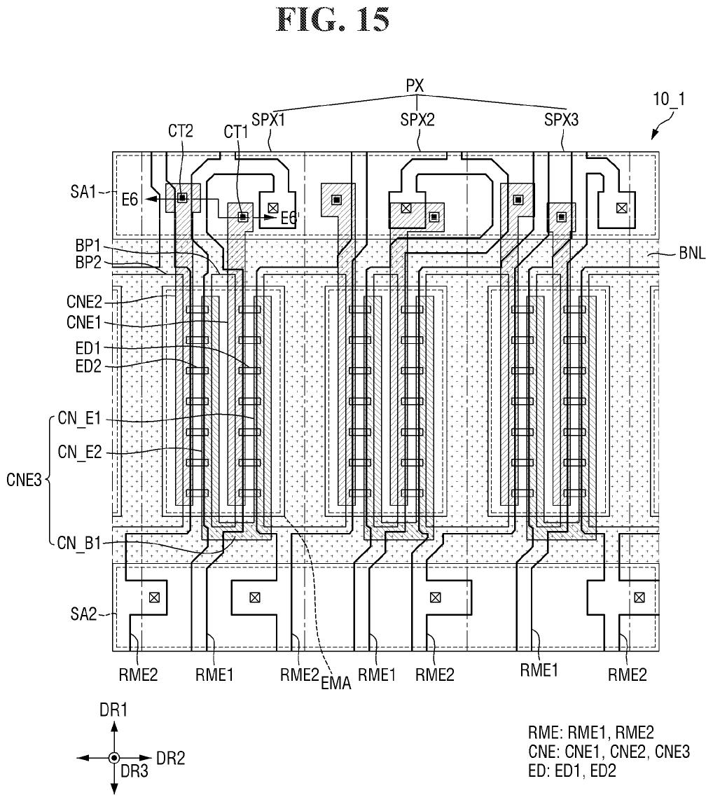

Hereinafter, a display device 10_1 according to one or more other embodiments will be described with reference to FIGS. 15 to 17.

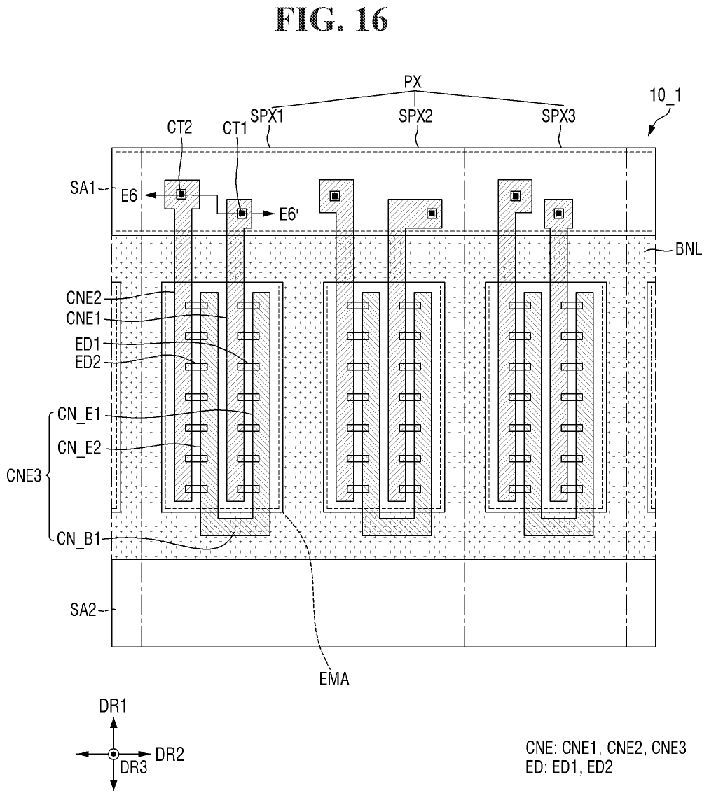

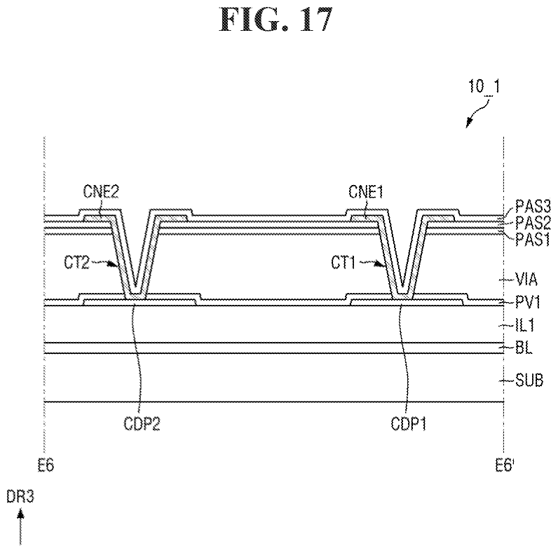

FIG. 15 is a plan view illustrating a display device according to one or more other embodiments of the disclosure. FIG. 16 is a plan view illustrating arrangement of connection electrodes, a bank layer and light emitting elements, which are located in one pixel of FIG. 15. FIG. 17 is a cross-sectional view taken along the line E6-E6′ of FIGS. 15 and 16.

Referring to FIGS. 15 to 17, unlike the previous embodiments, the first connection electrode CNE1 and the second connection electrode CNE2 of the connection electrode CNE are connected to the conductive patterns therebelow through a first contact portion CT1 and a second contact portion CT2, and further includes a third connection electrode CNE3.

The first connection electrode CNE1 may have a shape extended in the first direction DR1 and may be located on the first electrode body portion RMB1 of the first electrode RME1. The first connection electrode CNE1 may be located on the right side of the first electrode RME1 and the first bank pattern BP1 like the first sub-connection electrode (CNE11 of FIG. 4) of the previous embodiments. The second connection electrode CNE2 may be located on the second electrode body portion RMB2 of the second electrode RME2 with a shape extended in the first direction DR1. The second connection electrode CNE2 may be located on the right side of the second electrode RME2 and the second bank pattern BP2 like the fourth sub-connection electrode (CNE22 of FIG. 4) of the previous embodiments.

The first connection electrode CNE1 and the second connection electrode CNE2 may extend from the light emission area EMA in the first direction DR1, and may be located to reach the first sub-area SA1 positioned on the upper side of the light emission area EMA. The first connection electrode CNE1 may be in contact with the first conductive pattern CDP1 through the first contact portion CT1 formed on the first electrode RME1 in the first sub-area SA1. The second connection electrode CNE2 may be in contact with the second conductive pattern CDP2 through the second contact portion CT2 formed on the second electrode RME2 in the first sub-area SA1.

Referring to FIG. 17, the via layer VIA, the first insulating layer PAS1, and the second insulating layer PAS2 may include contact portions CT1 and CT2 located in the sub-area SA. The contact portions CT1 and CT2 may be located to overlap the conductive patterns CDP1 and CDP2, respectively. For example, the contact portions CT1 and CT2 may include first contact portions CT1 located to overlap the first conductive pattern CDP1, and second contact portions CT2 located to overlap the second conductive pattern CDP2. The first contact portions CT1 and the second contact portions CT2 may pass through the via layer VIA, the first insulating layer PAS1, and the second insulating layer PAS2 to expose a portion of the upper surface of the first conductive pattern CDP1 or the second conductive pattern CDP2 therebelow. The conductive patterns CDP1 and CDP2 exposed by the respective contact portions CT1 and CT2 may be in contact with the connection electrode CNE. The first conductive pattern CDP1 exposed by the first contact portion CT1 may be in contact with the first connection electrode CNE1. The second conductive pattern CDP2 exposed by the second contact portion CT2 may be in contact with the second connection electrode CNE2.

Referring back to FIGS. 15 and 16, the third connection electrode CNE3 may include extension portions CN_E1 and CN_E2 extended in the first direction DR1, and a first connection part CN_B1 connecting the extension portions CN_E1 and CN_E2. The first extension portion CN_E1 may be located on the second electrode RME2 while facing the first connection electrode CNE1 in the light emission area EMA. The first extension portion CN_E1 may be located on the second electrode body portion RMB2 of the second electrode RME2 of the second electrode line RML2 based on the first subpixel SPX1. The second extension portion CN_E2 may be located on the first electrode RME1 while facing the second connection electrode CNE2 in the light emission area EMA. The first connection portion CN_B1 may extend in the second direction DR2 on the bank layer BNL located below the light emission area EMA to connect the first extension portion CN_E1 with the second extension portion CN_E2. The third connection electrode CNE3 may be located on the light emission area EMA and the bank layer BNL, and may not be directly connected to the electrode RME or the conductive patterns CDP1 and CDP2. The second electrode RME2 located below the first extension portion CN_E1 may be electrically connected to the second voltage line VL2, and the second power voltage applied to the second electrode RME2 may not be transferred to the third connection electrode CNE3.

In concluding the detailed description, those skilled in the art will appreciate that many variations and modifications can be made to the disclosed embodiments without substantially departing from the aspects of the present disclosure. Therefore, the disclosed embodiments of the present disclosure are used in a generic and descriptive sense only and not for purposes of limitation.

What is claimed is:

1. A display device comprising:
a first electrode extended in a first direction;
a second electrode spaced apart from the first electrode in a second direction crossing the first direction, and extended in the first direction;
a bank layer extended in the second direction, and surrounding subpixels; and
a light emitting element on the first electrode and the second electrode,
wherein at least one of the first electrode or the second electrode comprises:
an electrode extension portion extended in the first direction; and
an electrode body portion connected to the electrode extension portion, and having a width that is greater than that of the electrode extension portion, and
wherein the bank layer overlaps the electrode body portion with a first width, and comprises an organic insulating material.

2. The display device of claim 1, wherein the first width is about 7 um or more.

3. The display device of claim 1, wherein the bank layer has a maximum thickness of about 2 um or more.

4. The display device of claim 1, wherein the bank layer has a dielectric constant of about 2 to about 4.

5. The display device of claim 1, wherein the bank layer is spaced apart from another bank layer in the first direction.

6. The display device of claim 1, wherein the first electrode comprises a first electrode extension portion extended in the first direction, and a first electrode body portion connected to the first electrode extension portion,
wherein the second electrode comprises a second electrode extension portion extended in the first direction, and a second electrode body portion connected to the second electrode extension portion, and
wherein the first electrode extension portion has a shape that is bent in a diagonal direction inclined toward the second electrode body portion from the first direction.

7. The display device of claim 6, wherein the second electrode extension portion has a shape that is bent in a diagonal direction inclined toward the first electrode body portion from the first direction.

8. The display device of claim 1, wherein the second electrode comprises a first electrode line and a second electrode line spaced apart from each other with the first electrode interposed therebetween, and
wherein the display device further comprises a first light emitting element between the first electrode and the first electrode line, and a second light emitting element between the first electrode and the second electrode line.

9. The display device of claim 8, further comprising:
a first connection electrode on the first electrode, and in contact with the first light emitting element; and
a second connection electrode on the second electrode, and in contact with the second light emitting element,
wherein the first connection electrode and the second connection electrode are on the electrode body portion.

10. The display device of claim 1, wherein the second electrode comprises the electrode body portion over adjacent ones of the subpixels.

11. The display device of claim 10, wherein a width of the electrode body portion in the second direction is greater than a width of the bank layer in the second direction.

12. The display device of claim 10, wherein the electrode body portion overlaps the bank layer between the adjacent ones of the subpixels.

13. The display device of claim 1, further comprising:
a first bank pattern extended in the second direction, and overlapped with the first electrode; and
a second bank pattern spaced apart from the first electrode in the first direction, extended in the second direction, and overlapped with the second electrode, wherein the electrode body portion overlaps any one of the first bank pattern and the second bank pattern, and
wherein the electrode extension portion is spaced apart from the first bank pattern and the second bank pattern in plan view.

14. The display device of claim 13, wherein the bank layer overlaps the first bank pattern and the second bank pattern.

15. A display device comprising:
a first electrode extended in a first direction;
a second electrode spaced apart from the first electrode in a second direction crossing the first direction, and extended in the first direction;
a bank layer extended in the second direction, and surrounding subpixels; and
a light emitting element on the first electrode and the second electrode,
wherein the first electrode comprises:
a first electrode extension portion extended in the first direction; and
a first electrode body portion connected to the first electrode extension portion, and having a width that is greater than that of the first electrode extension portion,
wherein the second electrode comprises:
a second electrode extension portion extended in the first direction; and
a second electrode body portion connected to the second electrode extension portion, and having a width that is greater than that of the second electrode extension portion, and
wherein the first electrode extension portion has a shape that is bent in a diagonal direction inclined toward the second electrode body portion from the first direction.

16. The display device of claim 15, wherein the bank layer overlaps the first electrode body portion and the second electrode body portion.

17. The display device of claim 15, wherein the bank layer overlaps the first electrode body portion and the second electrode body portion as much as about 7 um or more.

18. The display device of claim 15, wherein a width of the first electrode extension portion in the second direction is the same as that of the second electrode extension portion in the second direction.

19. The display device of claim 15, wherein a width of the first electrode body portion in the second direction is less than that of the second electrode body portion in the second direction.

20. The display device of claim 19, wherein the first electrode extension portion is connected to a conductive layer through a first electrode contact hole,
wherein the second electrode extension portion is connected to the conductive layer through a second electrode contact hole, and
wherein the first electrode contact hole and the second electrode contact hole are separated from the bank layer in plan view.
